(19) United States
(12) Patent Application Publication
(10) Pub. No.: US 2013/0282624 A1
(43) Pub. Date: Oct. 24, 2013

(54) Restaurant Equipment Monitoring and Control System and Method

(71) Applicants: Glenn Schackmuth, Oswego, IL (US); Roy H. Buchert, Oswego, IL (US); Balagru K. Veloo, Gurnee, IL (US)

(72) Inventors: Glenn Schackmuth, Oswego, IL (US); Roy H. Buchert, Oswego, IL (US); Balagru K. Veloo, Gurnee, IL (US)

(21) Appl. No.: 13/452,504

(22) Filed: Apr. 20, 2012

(51) Int. Cl. G08B 21/18; G01R 19/165

(52) U.S. Cl. CPC G08B 21/182; G01R 19/165
USPC 705/412; 340/657

(57) ABSTRACT

An integrated system and method are provided for energy, state and operation monitoring and control of restaurant kitchen and non-kitchen/building equipment. The system includes sensors and other data transmitting equipment communicatively connected to a local server and a computing device via a router. The data transmission equipment and server preferably utilize power-line data transmission as well as wireless data transmission. A dashboard application of the system provides a user interface guiding user responses to energy, state, and operational/service alerts and enabling user-input scheduled control settings. The system may also provide automatic feedback control of restaurant equipment.

### FIELD OF THE INVENTION

The present invention relates to systems and methods of monitoring and controlling restaurant equipment. More particularly, it relates to integrated systems and methods of monitoring operating states and energy usage of kitchen and non-kitchen equipment in a restaurant and responding to operating state and energy usage data.

### BACKGROUND OF THE INVENTION

Operating a high-volume, quick-service restaurant typically involves the use of several different appliances and other devices. Restaurant equipment is not limited to kitchen appliances, such as ovens, stoves, grills, refrigerators, freezers, ice-makers, soft drink mixers and dispensers, ice cream dispensers, coffee makers, toasters and fryers; but also includes dining-area, service counter and parking-lot equipment, such as interior and exterior lighting, signage, registers, and HVAC systems, for example. Most restaurant devices consume energy, and limiting the amount of this energy consumption is a significant concern for the profitability and efficient operation of a restaurant. It shall be understood that the term “restaurant device” as used herein refers generally to any device associated with the operation of a restaurant or maintenance of a restaurant environs or supporting land or structure, whether the device is a “kitchen device” (a device used to cook, hold, or prepare food) or a “non-kitchen device” (building or grounds equipment not directly related to food service), and the term shall encompass equipment that may otherwise be commonly referred to by other terms, including but not limited to “apparatus,” “appliance,” “installation,” “fixture,” “component,” and “unit.” Nonetheless, each restaurant device must operate in such a manner as to serve safe and quality food and to provide a safe and comfortable dining environment to customers of the restaurant, and these concerns impose energy demands on each restaurant device. Moreover, the primary concerns of restaurant staff are typically food quality and safety and customer service, leaving little time or focus to devote to energy efficiency.

A need therefore exists for a restaurant equipment monitoring system designed to reduce restaurant energy consumption and costs without interfering with the ability of the restaurant staff to focus on quality, safety and customer service.

### BRIEF SUMMARY OF THE INVENTION

The present invention provides a system and method that promotes awareness and understanding of restaurant operations, including but not limited to the state or condition of equipment operation and maintenance, product conditions, and energy usage at the restaurant and enterprise level, provides a restaurant with easy and timely access to detailed information regarding its current and historical consumption of energy, whether through the use of electricity, gas, water, or other utility or fuel, and facilitates energy usage comparisons (historical and device-to-device) within a given restaurant as well as comparative ranking (benchmarking) of similar restaurants in a configurable patch. Based on this self-comparison and benchmark ranking, the system provides a restaurant with simple diagnostics and solutions to help the restaurant reduce its energy consumption. The system not only helps to manage energy costs at a restaurant, but also where and when applicable, prepares a restaurant for government energy usage regulation and government as well as internal corporate energy reporting requirements. The system aggregates and provides accurate periodic (e.g. daily, weekly, monthly, and annual) energy consumption data for individual and groups of restaurants, for example, all restaurants in a city, state, province, region, or country. Furthermore, to streamline the incorporation of energy monitoring and control into the day-to-day operations of a restaurant, the system of the present invention integrates energy monitoring and state and operation monitoring into a single dashboard application. It is to be understood that state and operation monitoring can be done with or without and independently of the energy monitoring if desired. As used herein, the term “state” includes any condition, parameter, value, amount, history, and the like, and the term may be used as desired relative to equipment, products, and environment, for example,

In accordance with one aspect of the invention, an integrated restaurant equipment monitoring system is provided. The integrated restaurant equipment monitoring system includes a data management component that is communicatively linked to at least one energy-monitored restaurant device and configured to automatically receive energy use data pertaining to the energy-monitored restaurant device. The data management component includes a display device that is communicatively linked to a microprocessor and a memory. The microprocessor is programmed with instructions to cause the display device to transmit an alert to a human user when the data management component receives an energy use value for the energy-monitored restaurant device that is higher than a target value. The microprocessor is further programmed with instructions to cause the display device to display one or more suggested corrective actions for responding to the high energy use value. The integrated restaurant equipment monitoring system may further include at least one wireless sensor configured to sense the energy use data pertaining to the at least one energy-monitored restaurant device and to transmit the energy use data to the data management component. The system may further include a wireless router configured to relay the energy use data from the at least one wireless sensor to the data management component.

In accordance with another embodiment of the invention, the data management component may further be communicatively linked to at least one state-monitored restaurant device and configured to automatically receive state data pertaining to the at least one state-monitored restaurant device and the microprocessor is further programmed with instructions to cause the display device to transmit an alert to a human user when the data management component receives state data for any state-monitored restaurant device indicating an irregular state of the restaurant device that is different from a target state or range of target states and to cause the display device to display one or more suggested corrective actions for responding to the irregular state.

In accordance with another aspect of the invention, the data management component is further communicatively linked to at least one maintenance-monitored restaurant device and configured to automatically receive data indicating when the at least one maintenance-monitored restaurant device requires regular maintenance, and the microprocessor is further programmed with instructions to cause the display device to display a message indicating when the regular maintenance is required.

In accordance with another aspect of the invention, the data management component may further include a data input mechanism and the microprocessor is further programmed with instructions to cause the display device to display for each of the suggested corrective actions an estimate of the energy savings over a certain period of time that would result from taking that corrective action, to prompt a user to select one or more of the corrective actions using the data input mechanism, to input any selection made by the user, and to calculate and display an estimate of total energy savings over a certain time period that would result from taking all of the selected corrective actions.

The microprocessor may be still further programmed with instructions to receive and store in the memory a utility rate and to use the utility rate to calculate and display the estimates of energy savings as monetary equivalent values. The microprocessor in another embodiment may be further programmed with instructions to automatically query a remotely located server for the utility rate.

Numerous types of devices may be energy-monitored. Some non-limiting examples of kitchen devices that may be energy-monitored are any typical devices used in restaurants that utilize energy including, for example, freezers, refrigerators, food fryers, grills and non-limiting examples of non-kitchen devices that can be energy-monitored include, for example, any non-kitchen device that utilizes energy, such as parking lot lights, HVAC units, and interior lighting.

In accordance with another aspect of the invention, the microprocessor may be further programmed with instructions to cause to be stored in the memory an alert history including data pertaining to past instances of alert transmissions and to cause the display device to display the alert history data. The alert history data may include a total number of alerts transmitted for each restaurant device during one or more time periods.

In accordance with another aspect of the invention, the microprocessor may be programmed with instructions to cause to be stored in the memory an energy usage history including energy use data previously transmitted to the data management component, to calculate from the energy usage history total amounts of energy used by each energy-monitored restaurant device and by all of the energy-monitored restaurant devices during one or more time periods, and to cause the display device to display one or more of the total amounts of energy used, an indication of which device used, the total amount of energy or that the total amount of energy is for all of the energy-monitored restaurant devices, and an indication of the relevant time period. The microprocessor may be further programmed with instructions to receive and store in the memory one or more target amounts of energy corresponding to the displayed one or more of the total units of energy and to cause the display device to display the one or more target amounts of energy. The microprocessor may be still further programmed with instructions to receive and store in the memory one or more comparative amounts of energy used in other restaurants by a corresponding restaurant device or devices during a time period corresponding to the displayed one or more total amounts of energy and to cause the display device to display the one or more comparative amounts of energy.

In accordance with another embodiment of the invention, the microprocessor may be still further programmed with instructions to receive and store in the memory a utility rate and to use the utility rate to calculate and cause to be displayed the estimates of energy savings as monetary equivalent values. The microprocessor may be further programmed with instructions to receive input data identifying for at least one of the energy-monitored restaurant devices one or more utility power sources used to provide energy to the at least one of the energy-monitored restaurant devices, to determine a utility rate for the power source and to use the utility rate to calculate and cause to be displayed the estimates of energy savings as monetary equivalent values.

In accordance with another aspect of the invention, an integrated restaurant equipment monitoring and control system is provided. The integrated restaurant equipment monitoring and control system is composed of a data management component communicatively linked to a plurality of state-monitored restaurant devices and configured to automatically receive state data pertaining to at least one of the state-monitored restaurant devices. The data management component includes a microprocessor and the microprocessor is programmed with instructions to determine whether an irregular state has been detected for any state-monitored restaurant device that is different from a target value or outside a target range of values and to automatically initiate an action to cause the irregular state to return to the target value or range of values.

The data management component in another embodiment may further be communicatively linked to at least one energy-monitored restaurant device and configured to automatically receive energy use data pertaining to the energy-monitored restaurant device. The microprocessor in this embodiment may be programmed with instructions to cause the display device to transmit an alert to a human user when the data management component receives an energy use value for the energy-monitored restaurant device that is higher than a target value and to cause the display device to display one or more suggested corrective actions for responding to the high energy use value.

In accordance with another still another aspect of the invention, an integrated restaurant management method is provided. The integrated restaurant management method includes providing a data management component adapted to automatically receive energy use data from at least one energy-monitored device to which the data management component is communicatively connected, the data management component including a display device communicatively linked to a microprocessor and a memory, the microprocessor being programmed with instructions to cause the display device to transmit an alert to a human user when the data management component receives an energy use value for the energy-monitored device that is higher than a target value and to cause the display device to display one or more suggested corrective actions for responding to the high energy use value. The method further includes communicatively connecting the data management component to at least one energy-monitored restaurant device and when the display device transmits an alert indicating the high energy use value for an energy-monitored restaurant device and displays one or more suggested corrective actions for responding to the high energy use value, selecting and executing one or more of the suggested corrective actions.

In accordance with another embodiment of the method for integrated restaurant management, the method further includes inputting the selection of one or more of the suggested corrective actions into an input device of the data management component, the data management component being further configured to receive and store in the memory said selection. Further in accordance with the method, the inputting the selection causes the data management component to initiate execution of the selected corrective action.

In accordance with another aspect of the integrated restaurant management method, the data management component is further adapted to automatically receive state data from at least one state-monitored device to which the data management component is communicatively connected, and the microprocessor is further programmed with instructions to cause the display device to transmit an alert to a human user when the data management component receives data indicating an irregular state value for the state-monitored device that is different from a target state value or range of state values and the method further includes communicatively connecting at least one state-monitored restaurant device to the data management component and when the display device transmits an alert indicating an irregular state value for a state-monitored restaurant device and displays one or more suggested corrective actions for responding to the irregular state value, selects and executes one or more of the suggested corrective actions.

### BRIEF DESCRIPTION OF THE DRAWINGS

FIG. 1 is a schematic representation of the computing and control side of an integrated restaurant equipment monitoring and control system according to the invention.

FIG. 2 is a schematic representation of the restaurant equipment side of the system shown in FIG. 1.

FIG. 3 depicts a high- and normal-priority alert window according to one embodiment of a user interface of the invention.

FIG. 4 depicts a high-priority alert window according to one embodiment of a user interface of the invention.

FIG. 5 depicts a normal-priority alert window according to one embodiment of a user interface of the invention.

FIG. 6 depicts an energy usage alert window with suggestions according to one embodiment of a user interface of the invention.

FIG. 7 depicts an energy usage alert window with a recent suggestion selection history according to one embodiment of a user interface of the invention.

FIG. 8 depicts an energy usage suggestion history bar graph according to one embodiment of a user interface of the invention.

FIG. 9 depicts a day-to-day comparison bar graph of actual energy consumption versus target energy consumption in energy units according to one embodiment of a user interface of the invention.

FIG. 10 depicts a day-to-day comparison bar graph of actual versus target energy consumption in monetary units according to one embodiment of a user interface of the invention.

FIG. 11 depicts a bar graph for comparing energy consumption of various stores in a one-month period according to one embodiment of a user interface of the invention.

FIG. 12 depicts a bar graph representing energy usage over a target amount by device for various devices for a one-day period according to one embodiment of a user interface of the invention.

FIG. 13 depicts a bar graph representing energy usage over a target amount by hourly interval for a single device during a one-day period according to one embodiment of a user interface of the invention.

FIG. 14 depicts an overall energy usage suggestion checklist for a restaurant according to one embodiment of a user interface of the invention.

FIG. 15 depicts a bar graph showing an energy usage suggestion history for a restaurant according to one embodiment of a user interface of the invention.

FIG. 16 depicts a high-limit temperature alert window for a refrigerator with a quick fixes checklist according to one embodiment of a user interface of the invention.

FIG. 17 depicts the high-limit temperature alert window shown in FIG. 16 indicating recent quick-fix selections.

FIG. 18 depicts a bar graph showing a quick-fix selection history for the high-limit temperature alert illustrated in FIGS. 16 and 17.

FIG. 19 depicts a bar graph showing total numbers of alerts for various restaurant devices during a one-day period according to one embodiment of a user interface of the invention.

FIG. 20 depicts a bar graph showing daily alert totals for a refrigerator over a one-month period according to one embodiment of a user interface of the invention.

FIG. 21 depicts a suggestion checklist window for a wall freezer high-limit temperature alert according to one embodiment of a user interface of the invention.

FIG. 22 depicts a bar graph showing a total number of selections for each of a plurality of suggested responses to the high-limit temperature alert illustrated in FIG. 21 for a one-month period.

FIG. 23 depicts a left-to-right scrollable bar graph showing total numbers of alerts for each of several devices for a one-day period, and a list of recent alerts, according to one embodiment of a user interface of the invention.

FIG. 24 depicts a view of the bar graph shown in FIG. 23 scrolled horizontally to display alert totals for devices not shown in the view of FIG. 23.

FIG. 25 depicts a bar graph showing alert totals for various devices for a one-week period, and a list of recent alerts, according to one embodiment of a user interface of the invention.

FIG. 26 depicts a bar graph showing alert totals for various devices for a one-day period, and a list of recent alerts, according to one embodiment of a user interface of the invention.

FIG. 27 depicts a bar graph totaling alerts by type for a French fryer for a one-day period, and an indicator of the total resulting down time for the French fryer, according to one embodiment of a user interface of the invention.

FIG. 28 depicts a bar graph totaling suggestion selections in response to French fryer high-limit alerts for a one-day period, and an indicator of the total resulting down time for the French fryer, according to one embodiment of a user interface of the invention.

FIG. 29 depicts a high-limit temperature alert window for a French fryer with a suggestion checklist according to one embodiment of a user interface of the invention.

FIG. 30 depicts a bar graph totaling alerts by type for a right grill for a one-day period, and an indication of the total resulting down time for the right grill, according to one embodiment of a user interface of the invention.

FIG. 31 depicts a bar graph totaling selections of a plurality of suggestions in response to right-grill not-level alerts for a one-day period, and an indication of the total down time for the right grill, according to one embodiment of a user interface of the invention.

FIG. 32 depicts a right grill not-level alert window with a suggestion checklist according to one embodiment of a user interface of the invention.

FIG. 33 depicts a table logging downtime by incident for French fryer alerts during a one-day period according to one embodiment of a user interface of the invention.

FIG. 34 depicts a table logging downtime by day for a French fryer and a right grill during a one-week period according to one embodiment of a user interface of the invention.

FIG. 35 depicts temperature control and lighting control menus according to one embodiment of a user interface of the invention.

FIG. 36 depicts the temperature and lighting control menus shown in FIG. 35, with a low temperature alert pop-up message for a kitchen area.

FIG. 37 depicts a temperature alert window for a kitchen area, with a suggestion checklist, according to one embodiment of a user interface of the invention.

FIG. 38 depicts a change-temperature dialog box for a dining area according to one embodiment of a user interface of the invention.

FIG. 39 depicts a temporary set-point temperature override dialog box for a dining area according to one embodiment of a user interface of the invention.

FIG. 40 depicts a log-in dialog box according to one embodiment of a user interface of the invention.

FIG. 41 depicts a change permanent temperature set points dialog box for a dining area according to one embodiment of a user interface of the invention.

FIG. 42 depicts the change permanent temperature set points dialog box of FIG. 42 with a “cool” mode selected.

FIG. 43 depicts the temperature and lighting control menus shown in FIGS. 35 and 36, illustrating a temporary set-point-temperature override for a dining area, according to one embodiment of a user interface of the invention.

FIG. 44 depicts a restaurant temperature control schedule for setting operating hours and hours of occupancy of various restaurant areas according to one embodiment of a user interface of the invention.

FIG. 45 depicts a custom occupied schedule dialog box for a kitchen area according to one embodiment of a user interface of the invention.

FIG. 46 depicts the dialog box of FIG. 45 showing selection arrows for modifying a custom kitchen occupied schedule start time.

FIG. 47 depicts the dialog box of FIG. 46 further showing a keypad for entering a custom kitchen occupied schedule start day.

FIG. 48 depicts a custom occupied schedule dialog box for the operating hours of a restaurant according to one embodiment of a user interface of the invention.

FIG. 49 depicts a zone selection dialog box for selecting the zones to which a custom occupied schedule will apply to HVAC and lighting controls according to one embodiment of a user interface of the invention.

FIG. 50 depicts a reset week schedule confirmation dialog box according to one embodiment of a user interface of the invention.

FIG. 51 depicts a restaurant schedule monthly calendar according to one embodiment of a user interface of the invention.

FIG. 52 depicts a custom event schedule dialog box according to one embodiment of a user interface of the invention.

FIG. 53 depicts the dialog box of FIG. 52 showing a keypad for entering an event name into a name field.

FIG. 54 depicts an energy consumption monitoring settings menu according to one embodiment of a user interface of the invention.

### DETAILED DESCRIPTION OF THE INVENTION

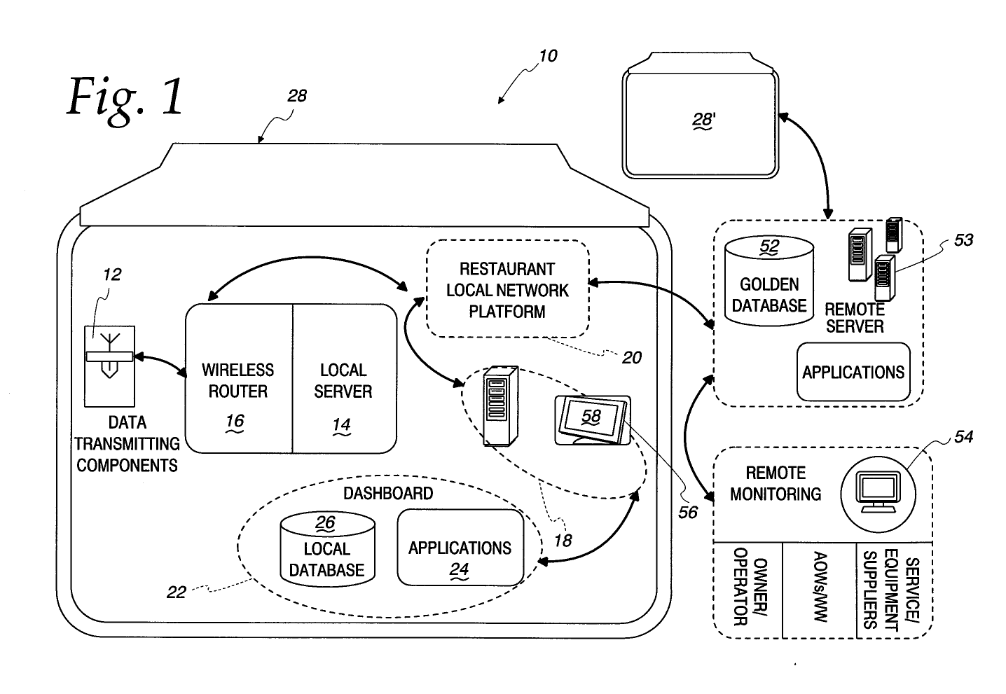

In accordance with the present invention, an integrated restaurant equipment energy usage, state and operation monitoring system and method are described in detail in this section, with reference to the accompanying figures. As depicted schematically in FIG. 1, system 10 includes data transmitting components 12 communicatively linked to a local server 14 via a router 16 (depicted and described in the preferred embodiment as a wireless router, although wired routers are also within the scope of the invention) and at least one computing/client device 18, which is preferably a “thin client” device configured to run cloud- and server-based applications, utilizing its own microprocessor and memory and/or those of local server 14 and/or one or more remotely located computing devices connected to computing device 18 via the internet, and physically adapted to tolerate a harsh kitchen environment. Local server 14 is linked to computing device 18 via a suitable restaurant network platform 20, and computing device 18 operates a dashboard application (“dashboard”) 22, utilizing software applications 24 and a local database 26 which may be stored in local server 14, stored in computing device 18, or cloud-based, making use of remotely located processing and/or memory via an internet connection. The foregoing components of system 10 are located within a restaurant 28, while other components of system 10, which will be discussed in more detail below, are connected to the in-restaurant components through an internet connection via restaurant network platform 20.

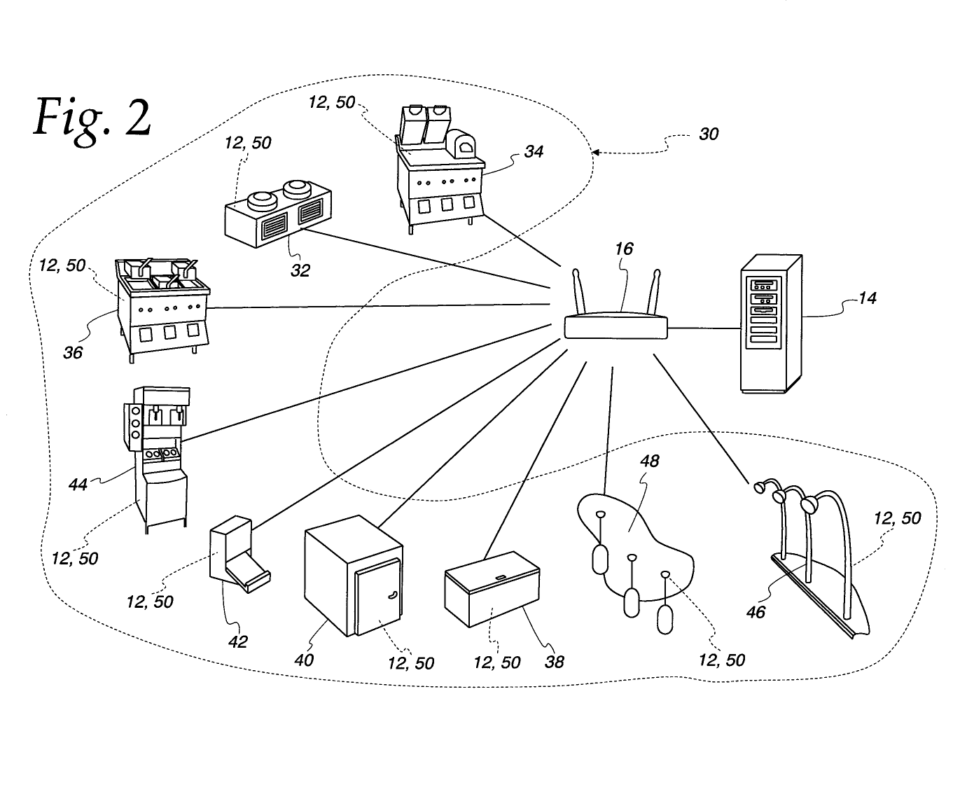

System 10 is configured to perform energy monitoring for incoming electric, gas and water service for restaurant 28. Preferably, system 10 also monitors energy usage, states, and/or settings of each of several individual restaurant devices 30. Some or all of restaurant devices 30 may be “energy-monitored devices” (devices having their energy usage monitored by system 10), “state-monitored devices” (devices having their states monitored by system 10), or both. As depicted in FIG. 2, restaurant devices 30 may include but are not limited to HVAC unit 32 (which may for example be a rooftop unit or “RTU”), a grill 34, a French fryer 36, a reach-in freezer 38, a walk-in freezer 40, a toaster 42, a shake and/or sundae machine 44, parking lot lighting 46, and interior lighting 48, as well as other devices not depicted graphically, such as refrigerators, ice machines, prep tables, food warming/holding/rethermalizing cabinets, and/or beverage dispensers, in accordance with the needs of restaurant 28 and/or the associated enterprise. It is important that energy usage monitoring results of system 10 be consistent with those of electric, gas, and water service utility meters so that the information provided by system 10 reliably reflects the economic impact of the energy use of restaurant 28. In fact, it is advantageous for the usage monitoring results of system 10 to be at least as reliable as, if not more reliable than, those of existing utility meters, so that any results of system 10 that are inconsistent with those of existing utility meters may alert the management of restaurant 28 to a possible malfunction of the existing utility meters. System 10 is also capable of taking advantage of utility pulse meters, where available, eliminating the need for service entrance current transformers.

Suitable components and arrangements of system 10, including but not limited to local server 14 (including any data storage and computing components), router 16, and data transmitting components 12 will be well known to those skilled in the art and can be selected desired. As a non-limiting example, suitable power line data transport and software components are available from the Echelon Corporation under the trade names LonWorks® and LNS®. Other suitable equipment and software can also be used as well known to those skilled in the art. Advantageously, power line data transport avoids the need for additional cable runs. The components of system 10 may utilize “twisted pair” technology, described by Consumer Electronics Association (CEA) standard ANSI/CEA 709.3. Data transmitting components 12 typically include sensors 50 and/or built-in components of restaurant devices 30, as explained in more detail below (neither are depicted graphically, but reference numerals are included in FIG. 2 to indicate that sensors 50 and/or data transmitting components 12 may be located on or in any or each of restaurant devices 30. Sensors 50 may be any suitable sensor as desired for sensing one or more chosen states or parameters. Sensors 50 may also perform functions other than sensing. Depending on the needs of particular installation, sensors 50 may be capable of being retrofitted into an existing restaurant with minimal if any interruption of equipment operation. Sensors 50 are connected to local server 14 via a hardwired or preferably wireless connection. Local server 14 may comprise LonWorks® server components, for example, that can be used to migrate data from kitchen and non-kitchen restaurant equipment. More particularly, local server 14 may be an iLon® Smart Server, for example, including a power line router, housed in a custom enclosure. Suitable communications hardware may be housed in some or all of restaurant devices 30, which may be LonWorks® communications hardware or some other suitable communications hardware as will be well known to those skilled in the art. Local database 26, which may be a LonWorks® LNS database, for example, preferably stores present and historical data and operating profiles pertaining to every device that connects to system 10. In addition, a remotely located “golden database” 52 associated with a remote server 53 may contain and provide change control for all system wide profiles. Golden database 52 is communicatively linked to restaurant network platform 20 via an internet connection and is preferably remotely monitored and controlled by an administrative computing/client device (“administrative client”) 54. Golden database 52 facilitates “auto commissioning;” i.e., system 10 may be configured for the addition of a new device by a user of administrative client 54 without direct access to local database 26.

In addition to sensing a desired parameter or state, sensors 50 may also transmit data wirelessly, and system 10 is preferably capable of reading wireless transmissions from a plurality, for example twenty or more, of sensors 50 mounted on various electrical, gas and water systems and/or on or within restaurant devices 30 themselves where appropriate. Sensors 50 communicate with local server 14 using any suitable common communication channel. If the output of sensors 50 is a serial message, packets with data are preferably sent at a regular heartbeat frequency with a suitably defined time interval. Sensors 50 have an operation range chosen for a particular application, which depending on the application could range from, for example, from −40° F./−40° C. to 125° F./50° C. or as otherwise desired such as 250-450° F., with a resolution of, for example, 1° C., and a humidity operating range of 0-95%. Router 16 should be capable of supporting temperature, current-monitoring, and other types of sensor 50 as needed for restaurant 28.

System 10 may also be further configured to send and/or receive data signals to or from one or more of data transmitting components 12 that are built-in components (not shown) of one or more of restaurant devices 30 themselves, in addition to sensors 50. For example, certain discrete states, like whether a grill platen is lifted or whether a freezer or refrigerator door is open, may more typically be detected or sensed and transmitted by a component integral to a restaurant device 30 itself, rather than by a sensor 50 that is separate from the restaurant device 30. Also, many parameters or states pertaining to restaurant devices 30, which may be broadly termed “settings,” relate to how devices 30 are being directed to perform, rather than how they are actually performing, such as simple on/off, set-point temperature, power level, or fan speed settings, to name a few examples. Data indicating the setting itself may be sensed in any suitable manner and transmitted directly from the restaurant device 30 in question as soon as the setting is put in place, such as by the manual turning of a dial or pressing of a button or switch. More complex settings, such as programmed instructions for a restaurant device 30 to perform a cooking process comprising a sequence of different operations, may nonetheless be coded and transmitted to system 10 by the restaurant device 30 in question. In embodiments of the invention in which system 10 performs control as well as monitoring functions, a setting may be put in place by an instruction sent to a restaurant device 30 from system 10 itself, in which case system 10 may simply log the setting by logging the sending of the instruction, rather than receiving a signal from the restaurant device 30 indicating the setting. It will be understood that monitoring settings in addition to measurable states enables system 10 to facilitate analysis of whether and how efficiently restaurant devices 30 are able to attain the actual measurable states that are intended to be attained when particular settings are selected.

Router 16 interfaces system 10 with sensors 50 and any other data transmitting component 12 that sends and receives data signals to and from system 10 in accordance with the invention. Preferably, all sensors 50 and other data transmitting components 12 are “plug and play” in the sense that they are commissioned and identified by router 16 automatically. Wireless operation range should meet restaurant requirements with no expert installation required. In addition, router 16 may have to meet a specific protocol requirement to communicate with the specialized local server 14 of the invention.

Dashboard 22 provides a means of displaying alerts on and facilitating the resolution of failures and abnormal equipment energy usage, operation/function, or states. A history of alerts of a certain type or any type may also be logged and displayed for the whole restaurant 28 and/or broken down by restaurant device 30. Additionally, dashboard 22 prompts user input to be received via a user-input device of computing device 18 and processed by the dashboard application. The user input device is preferably a touch screen 58 that forms part of display device 56, but it may alternatively be any other conventional user input device, including but not limited to a keyboard, mouse, and/or microphone, for example.

Dashboard 22 can provide an intuitive and easy-to-use interface so that use of dashboard 22 places minimal if any burden on restaurant staff in addition to their core duties of making food and serving customers. Dashboard 22 is preferably configured to operate on a cloud platform via computing device 18 and to display the user interface on a display device 56 of client device 18. Advantageously, operating on a cloud platform permits the dashboard application to be smoothly upgraded to its latest version when appropriate and in as many restaurants as desired, ranging from a single-restaurant to global upgrade.

The manner in which the alert is “displayed” need not be visual, and “displaying” an alert for purposes of this application shall include presenting the alert visually as a textual message, a graphical image, and/or a simple illuminated or flashing light; sounding the alert as an audible alarm and/or audible spoken message; and/or presenting the alert tactilely, for example as a vibrating alarm on a mobile handheld device. An alert message may be sent and displayed, for example, based on an elapsed time at which a temperature sensed in a particular restaurant device 30 is above or below a threshold temperature and/or following a time period in which the energy usage of a particular restaurant device 30 or of restaurant 28 as a whole is above a threshold level. Preferably, a user is able to select a preferred alert mode from the foregoing or other suitable modes. In a restaurant setting, the mode and placement of the alert mechanism is preferably selected so that the alert readily captures the attention of the appropriate restaurant staff even when they are involved in their core tasks, while at the same time generally going unnoticed by restaurant customers, so as not to startle or cause undue concern to the customers.

A troubleshooting or suggested response checklist may be advantageously displayed for a particular alert displayed by dashboard 22, either automatically or when a user selects to expand an alert shown in the user interface of dashboard 22, for example by touching an alert message or icon. The troubleshooting checklist may include a list of suggested responsive actions. When the alert pertains to energy monitoring, each suggested responsive action may be displayed with an associated energy savings value, and when responsive actions are selected, amounts of energy savings per month (or other appropriate time period) by taking the selected actions are summed automatically and displayed as a total projected savings.

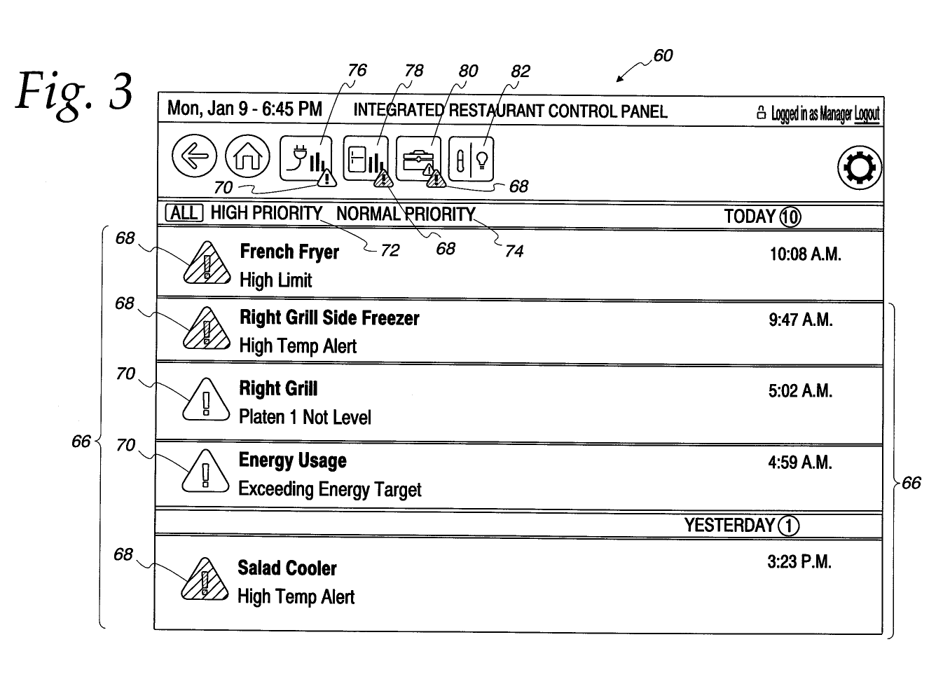

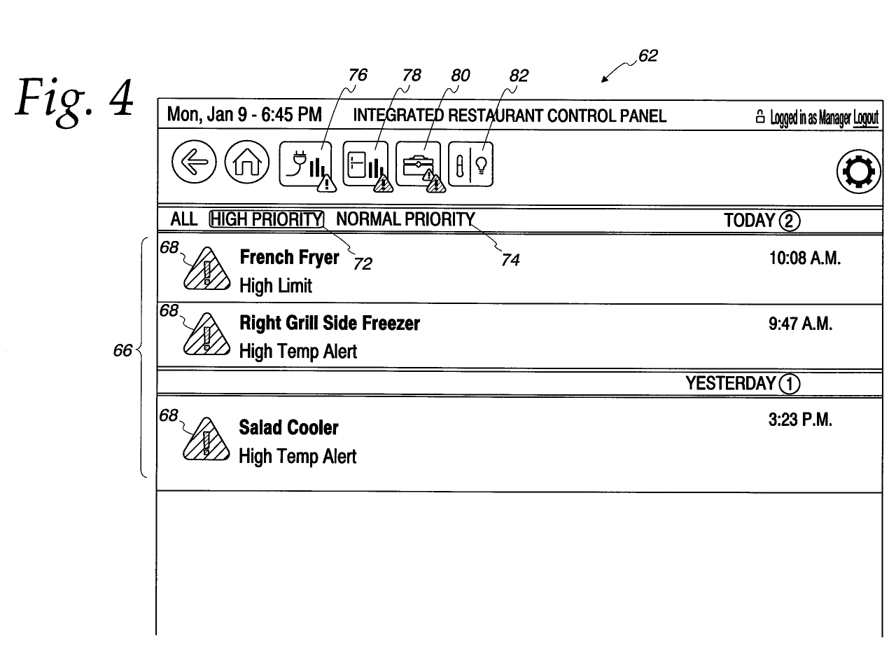

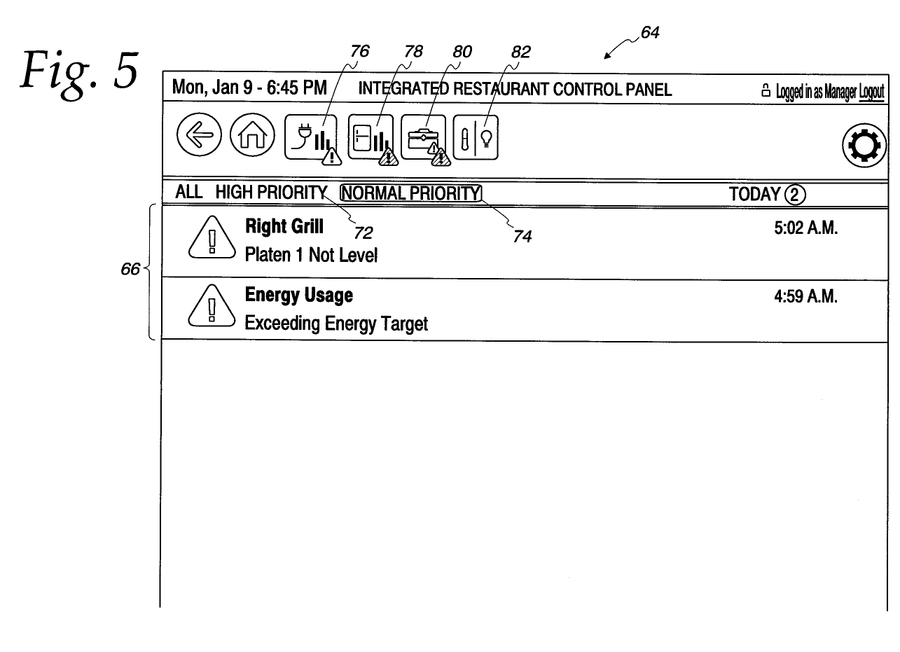

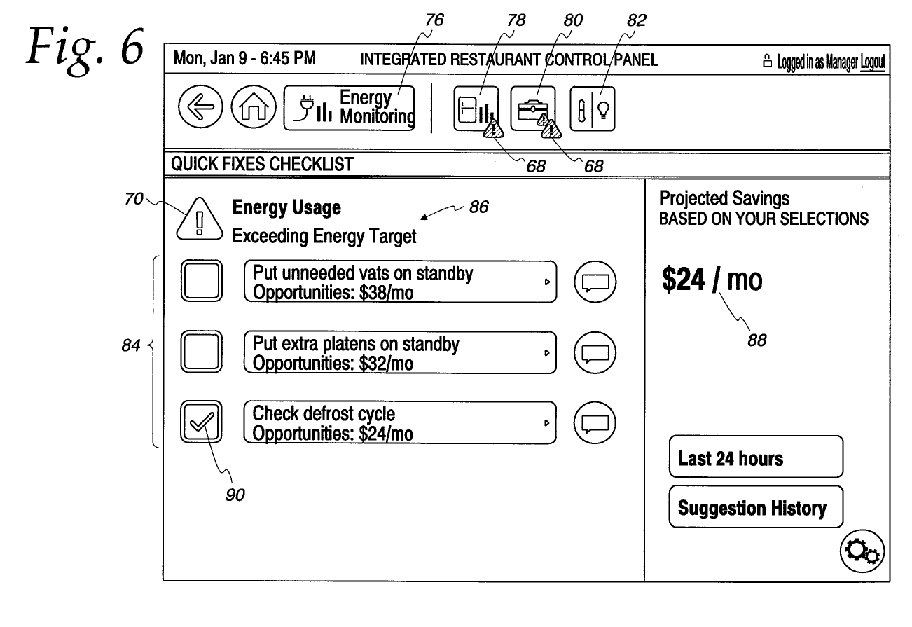

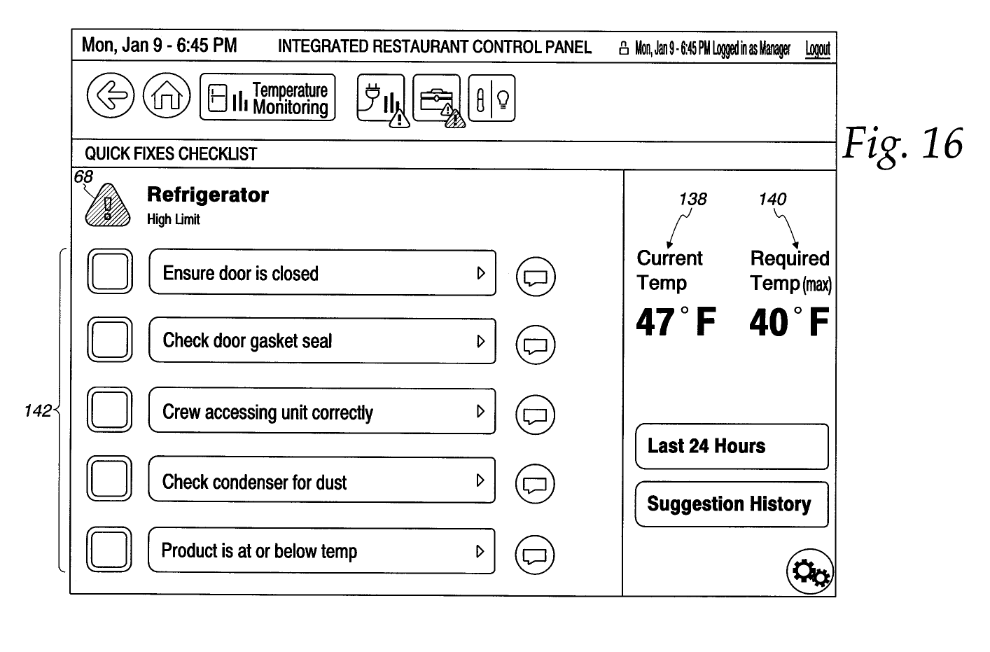

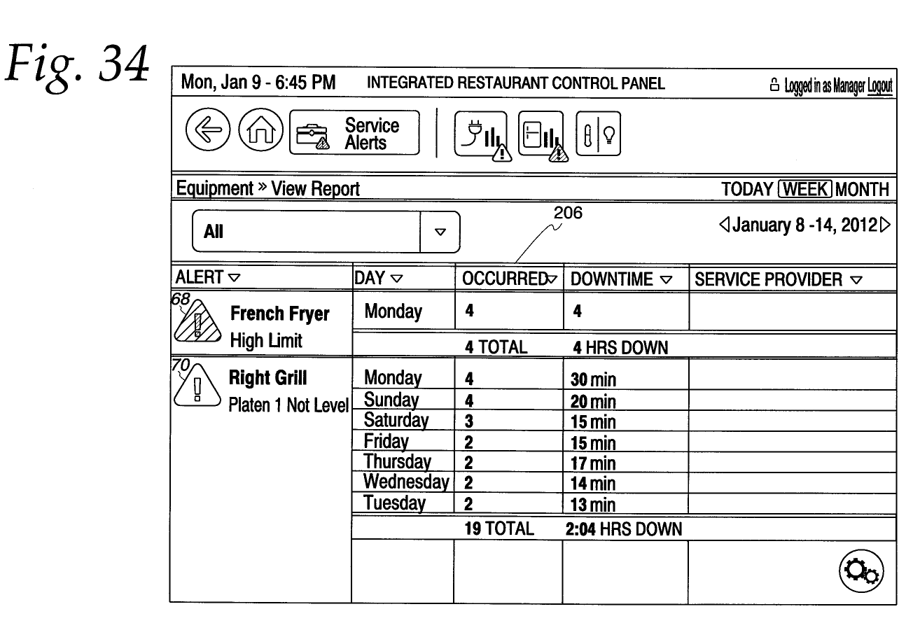

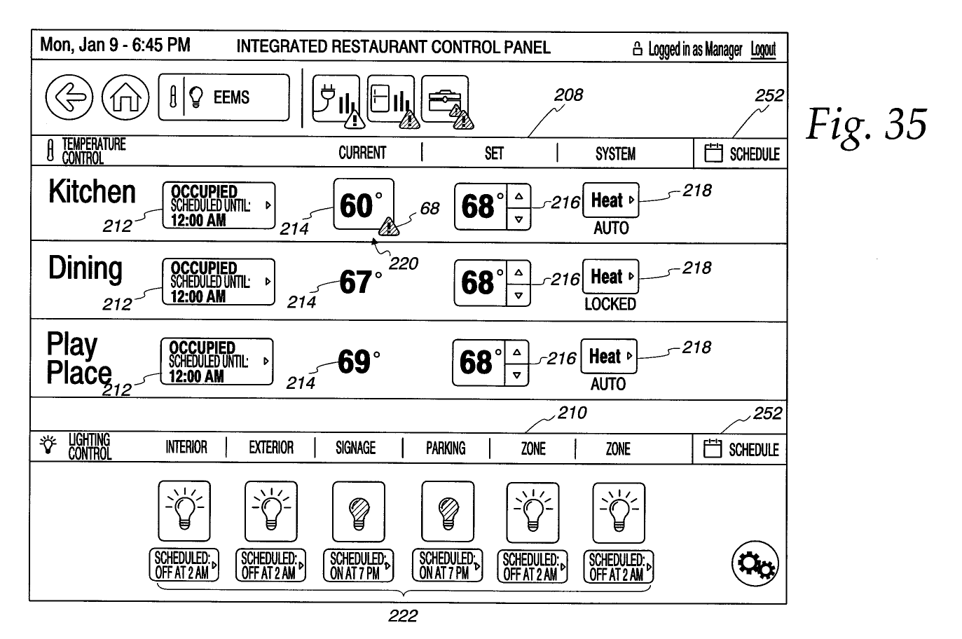

One example of the graphical display frames of a user interface of dashboard 22 is depicted in FIGS. 3-54. FIGS. 3-5 depict homepage alert windows 60, 62, and 64 respectively. Alert window 60 shown in FIG. 3 includes a plurality of alert messages 66, each indicated as high- or normal-priority by a high-priority icon 68 or normal-priority icon 70, respectively. In alert window 60, all alerts are displayed, and in alert windows 62 and 64, shown in FIGS. 4 and 5, respectively, only high priority or only normal priority alerts are displayed, respectively, by a user selecting a respective tab 72 or 74. Button icons 76, 78, 80, and 82 appearing at the top of all menu screens within the user interface of dashboard 22 permit a user to navigate to an energy monitoring page, a temperature monitoring page, a service alerts page, and an expandable energy management system (“EEMS”) page for automated HVAC and lighting control system scheduling and overriding, respectively. FIGS. 6-15 depict screens accessed via the energy monitoring page, FIGS. 16-22 depict screens accessed via the temperature monitoring page, FIGS. 23-34 depict user interface screens accessed via the service alerts page, and FIGS. 35-53 depict screens accessed via the EEMS page.

With reference to FIGS. 6-15, it will be seen that dashboard 22 is configured to display information related to a restaurant's energy consumption on a periodic (daily, monthly and yearly, e.g.) basis in a textual and graphical manner that is intuitive and easily understood by restaurant staff. A long-term history of restaurant-wide and/or restaurant-device energy consumption may be generated and stored in system 10 for a revolving period of, for example, the past five years. Additionally, dashboard 22 may display short-interval consumption detail “snapshots” of all measured loads, for example over 15-minute intervals (not shown), to facilitate troubleshooting at the restaurant level.

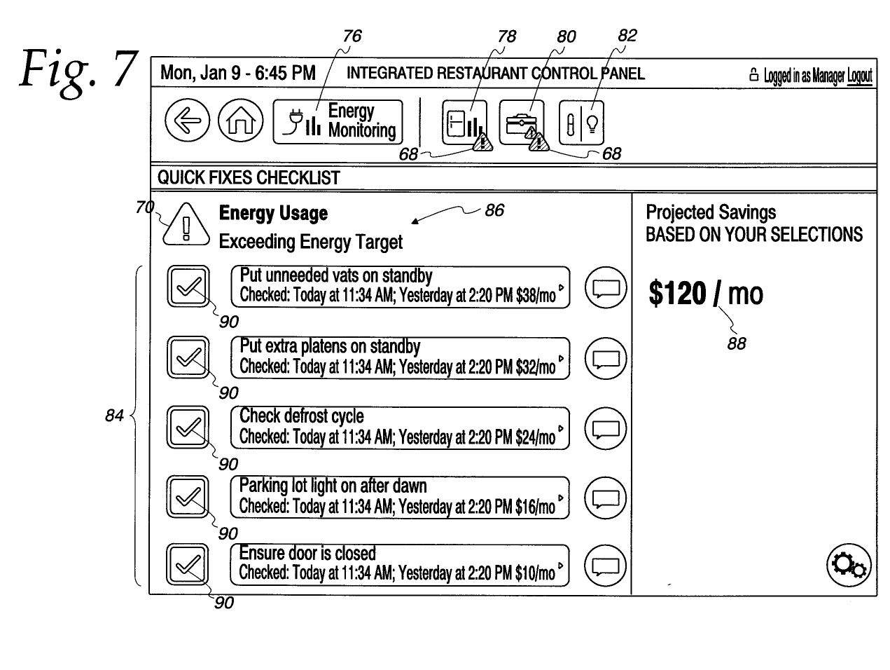

Turning to FIGS. 6 and 7, dashboard 22 may provide energy saving suggestions 84 in response to an exceeding energy target alert 86. Projected dollar amounts of savings are indicated in FIG. 6 for each energy saving suggestion 84, and a projected savings total 88 is displayed based on a user selection 90. A 24-hour history of suggestions 84 and user selections 90 is depicted in FIG. 7, with a projected savings total 88 depicted as a sum of the savings based on each user selection.

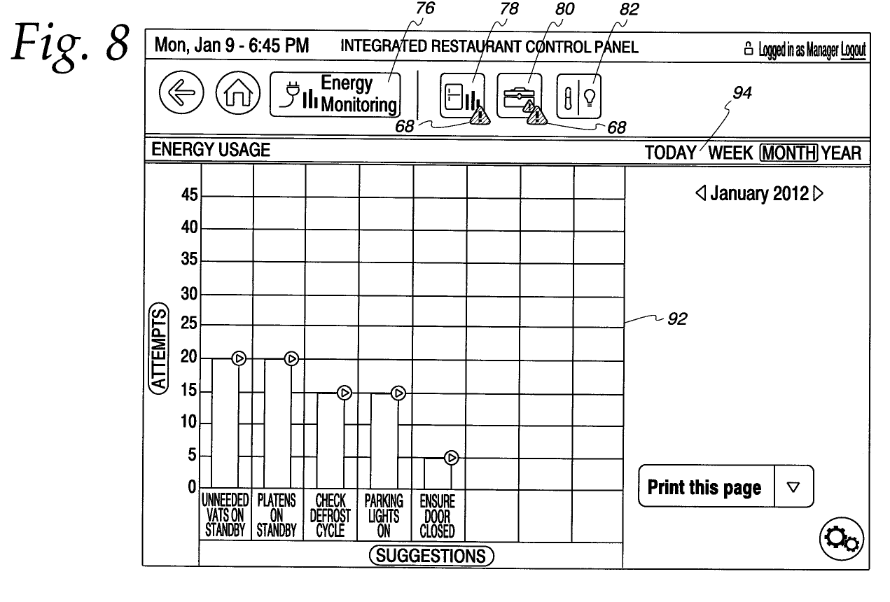

FIG. 8 shows a hypothetical history of energy saving suggestions for the month of January 2012 in the form of a bar graph 92 depicting graphically the number of times each suggestion has been made. A different time period may be illustrated by a user selecting the desired time period (today, week, month, year) from a time period selector 94, which appears in many of the user interface screens of dashboard 22. For example, this is the case for all energy monitoring graphs shown in FIGS. 8-13.

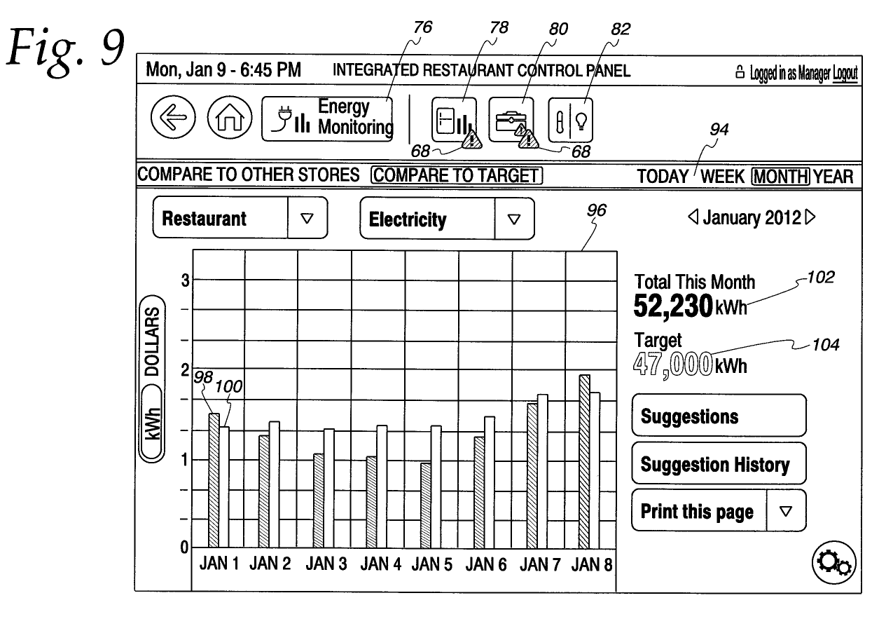

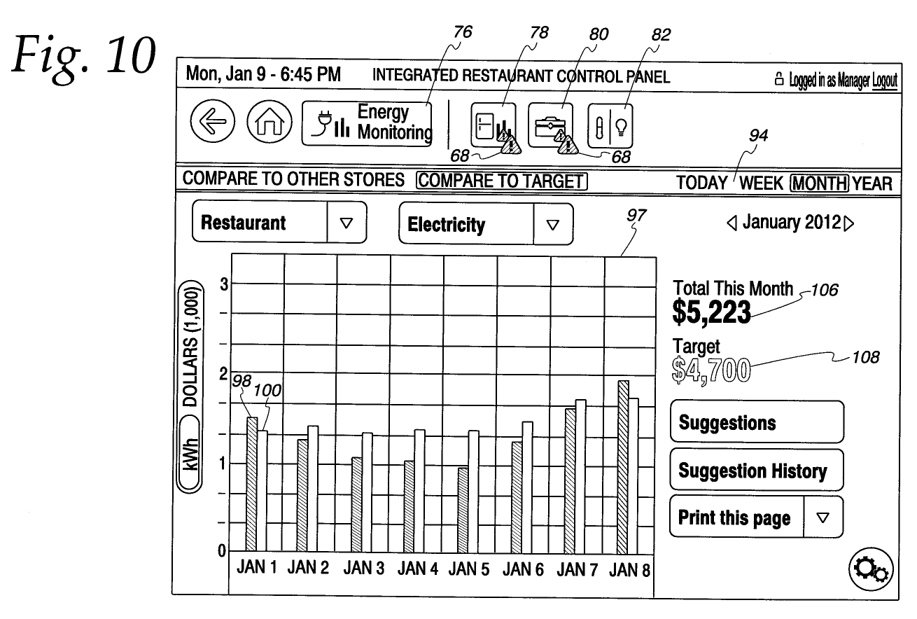

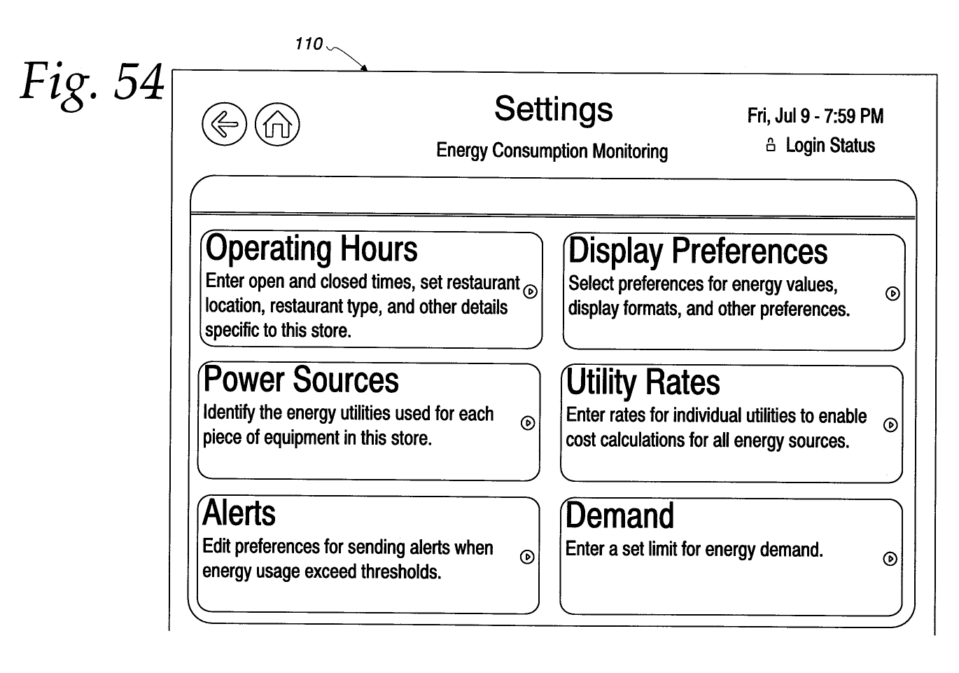

With reference to FIGS. 9-13, example user interface screens are depicted showing how energy consumption amounts may be represented graphically by dashboard 22. FIGS. 9 and 10 show a graphical day-to-day comparison and numerical monthly total of actual energy consumed versus target energy consumed. In FIGS. 9 and 10, bar graphs 96, 97 depict for each day of a calendar month a pair of vertical bars consisting of a darkly shaded actual consumption bar 98 on the left-hand side and a lightly shaded target consumption bar 100 on the right-hand side. As an additional visual cue, actual consumption bar 98 may, for example, be colored red when energy consumption exceeds the target for a given day, and green when energy consumption is less than the target. In FIG. 9, a monthly actual energy consumption total 102 is presented numerically in energy units (in this case kWh) next to a target energy consumption total 104, while in FIG. 10, similar totals 106 and 108 are presented in monetary units (in this case $). Like actual consumption bars 98, actual energy consumption totals 102, 106 may be color-coded based on whether they exceed or are less than respective target energy consumption totals 104, 108. It will be noted that preferred energy and monetary units to be displayed may be customized, either automatically, as when cloud-based dashboard 22 detects that it is being run on a client computing device 18 in a particular region, for example; or manually, either by individually selecting preferences or selecting a default group of preferences for a desired region. Energy and monetary units may be among the “display preferences” accessible via an energy monitoring settings menu 110 depicted in FIG. 54.

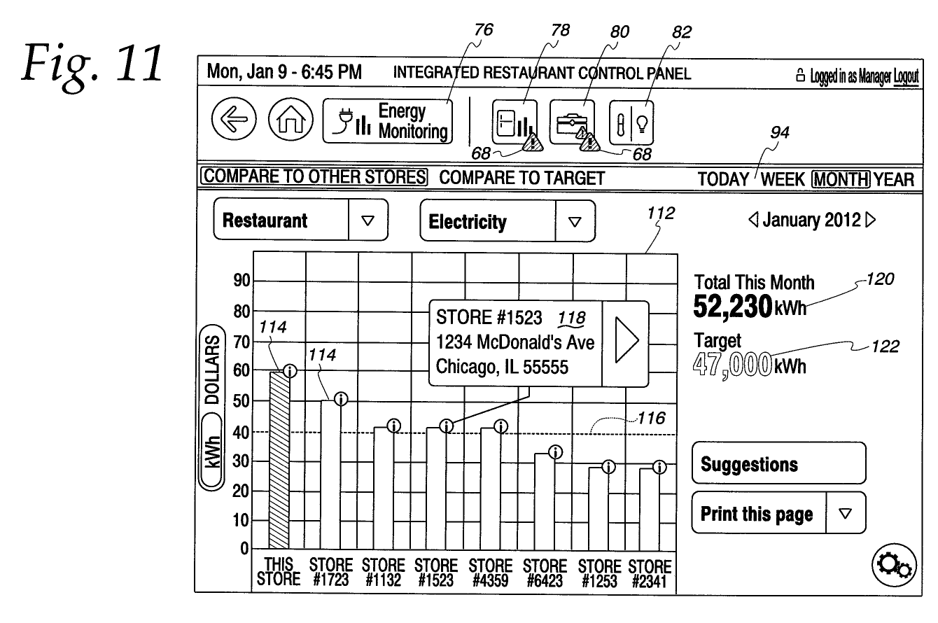

Turning to FIG. 11, dashboard 22 is also capable of displaying comparisons of a restaurant's consumption in a given period to that of other restaurants, for example in a bar graph 112 that is intuitive and easily understood by the restaurant staff. In the depicted example, bars 114 indicating energy usage by restaurant are arranged in descending order of energy usage from left to right, in this case the highest bar 114 on the far left representing “this store” (the home or subject restaurant 28). A dashed line 116 overlain on bar graph 112 may indicate an average total energy consumption for the restaurants displayed, the bar representing “this store” may be more darkly shaded for contrast from other restaurants, and each bar may be color-coded based on whether the monthly total for that restaurant exceeds or is less than the target monthly total. A pop-up information bubble 118 may be displayed for a given restaurant by clicking on that restaurant's bar 114. A monthly energy consumption total 120 for the subject restaurant 28 is again depicted as a numerical figure next to a target total 122 on the right side of the screen. Preferably, although not expressly indicated in FIG. 11, each restaurant's energy use is normalized based on factors beyond the control of restaurant staff, restaurant management, and system 10, such as for example, weather and operating or sales volume metrics, as explained in more detail below, so that the comparison is a relevant indicator of how each restaurant is performing in terms of energy efficiency.

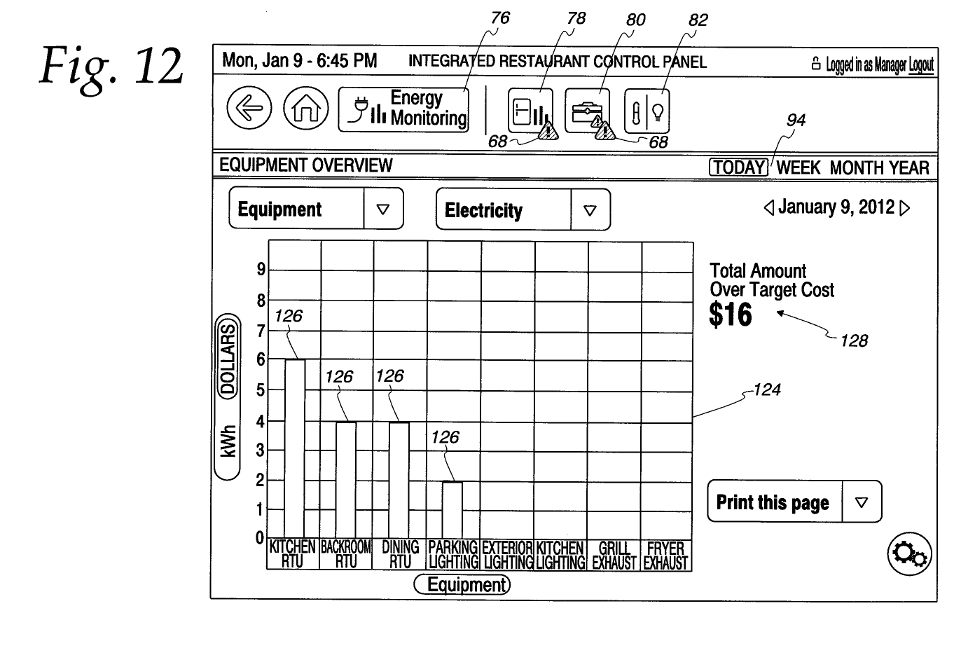

A breakdown of energy consumption by equipment item is represented by a bar graph 124 shown in FIG. 12, where each bar 126 depicts an amount measured in dollars by which the equipment item in question exceeds target energy usage for the day Jan. 9, 2012, and the total amount 128 by which the target is exceeded is shown as a numeric figure in dollars. In the example shown in FIG. 12, to the extent that kitchen and exterior lighting and grill and fryer exhaust may be operating at below target cost, the amount is not offset against the over-target amounts corresponding to other units, so that the total amount 128 represents a savings/profit opportunity rather than a net over-target amount of all the equipment. FIG. 13, on the other hand, shows a bar graph 130 representing an hourly breakdown for just one equipment item, a kitchen RTU, bars 132 depicting amounts by which target cost is exceeded for hourly time intervals, and providing a total amount over target cost 134 as a dollar figure. Similarly to bar graph 124 of FIG. 12, bar graph 130 of FIG. 13 does not represent any amount below target cost for any hourly interval, nor is any hourly amount below target cost offset against total amount 134, so that total amount 134 represents the total savings opportunity available by addressing “problem hours.” Alternatively, displaying a net amount over target that offsets below-target hours against over-target hours is also within the scope of the invention, though not shown.

Although not shown in the Figures, dashboard 22 may also be capable of displaying comparisons of a restaurant's current consumption to its historical consumption (for example, daily, weekly, monthly, yearly).

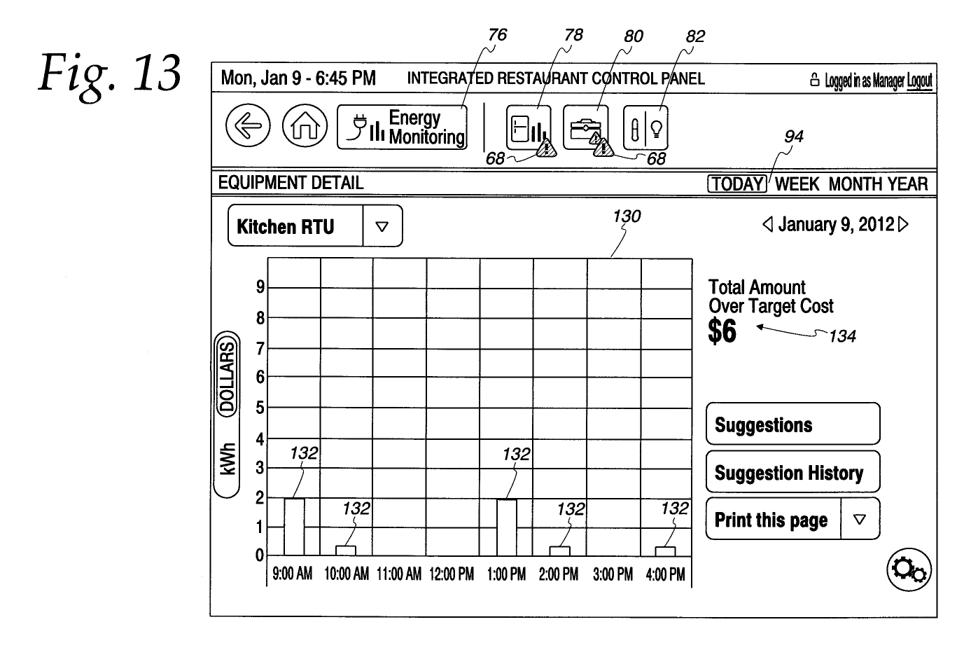

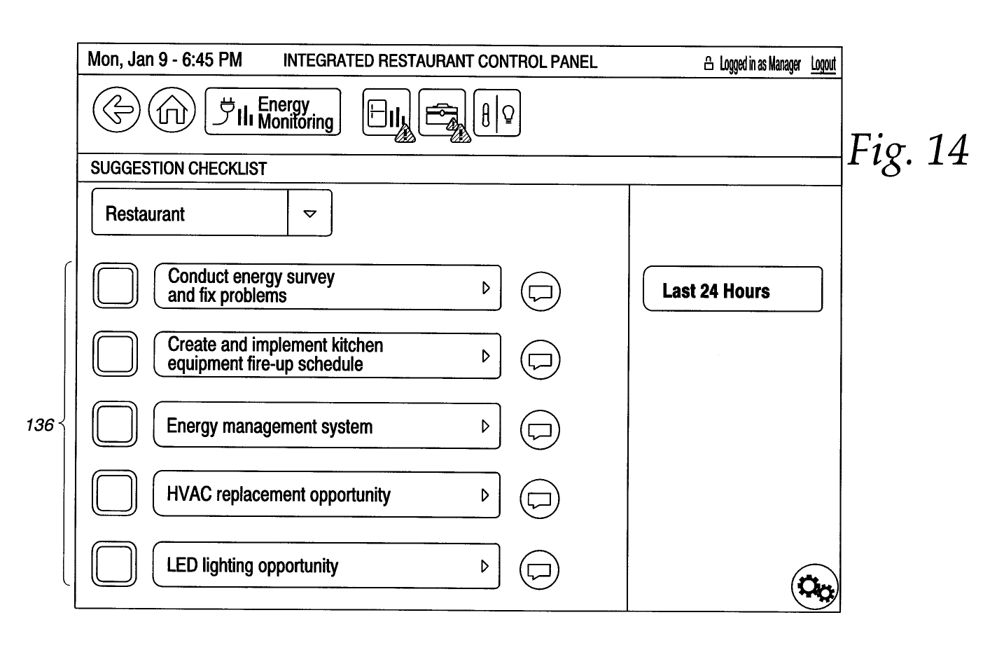

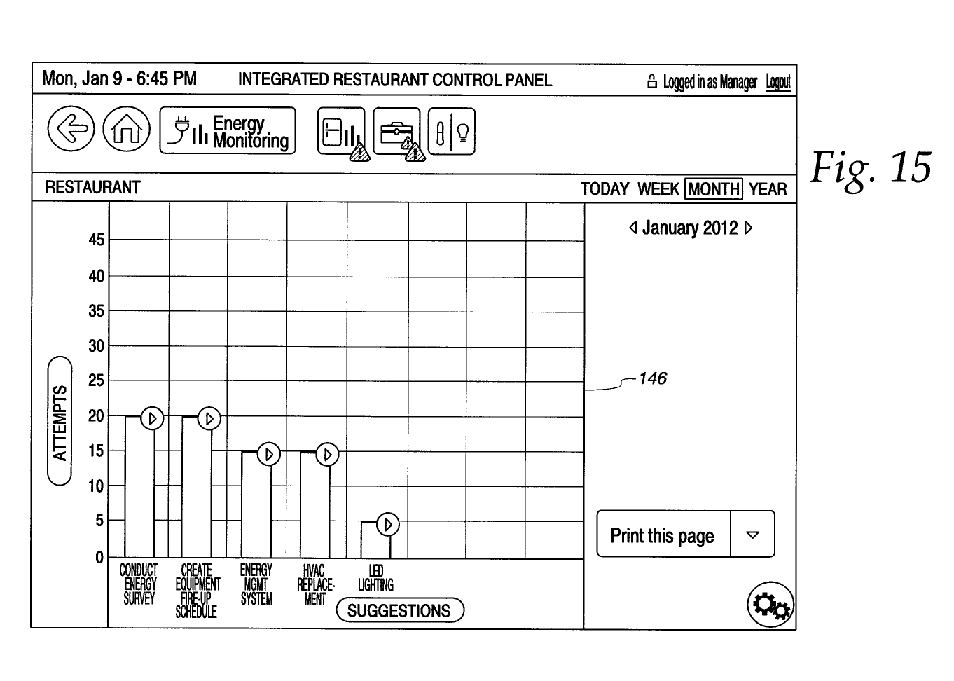

Based on energy consumption comparison results, dashboard 22 provides and displays recommendations that are actionable at the restaurant level to help the subject restaurant 28 reduce its consumption. Dashboard 22 may display recommendations directly or advise restaurant staff where to find recommendations or tools to help reduce the restaurant's energy consumption. Thus, FIG. 14 depicts a screen providing a checklist of suggestions 136 for overall restaurant energy savings, while FIG. 15 depicts a bar graph 146 illustrating total numbers of times that suggestions 136 were presented by dashboard 22 in the month of January 2012.

In connection with the energy cash savings projection function of dashboard 22, a microprocessor(s) associated with or communicatively connected to computing device 18 must calculate projected energy savings for the given time period and convert those savings into monetary savings using appropriate utility rates. Although not illustrated in the Figures, dashboard 22 may be configured for the utility rates to be entered manually, or obtained automatically. One way that system 10 may obtain utility rates automatically is to periodically query a remote database, such as a public database of rates of utility providers, or a database belonging to the applicable utility provider, where a user has manually entered or selected a particular utility provider via the user interface of dashboard 22. For example, the appropriate utility energy or power source (e.g., gas, electric, propane, or water; not to be confused with the utility provider) may be identified manually for each of restaurant devices 30, as seen for example in FIG. 54. For each energy source, a utility provider may be specified manually via dashboard 22, and the manually entered (screen not shown) energy source and utility provider information may be stored for reference in any memory storage device associated with or communicatively connected to computing device 18.

In one embodiment, target energy use values may be fixed values, which are either entered locally into system 10 via dashboard 22 or uploaded to system 10 from a central remote location. More preferably, either the energy consumption data or the target value is calculated from extrinsic factors that change over time or vary from store to store, and which are outside of the control of system 10 and the restaurant staff, optionally by starting with a universal nominal target value and normalizing the nominal target value to account for the extrinsic factors. Such extrinsic factors may include, for example, transaction volume, building size, and weather. As examples of normalization, one or more formulas or algorithms may be implemented by the dashboard application to calculate or otherwise determine variable energy usage target values, based on one or more cumulative transactional metrics such as net revenue, total number of sales transactions, and/or total product output quantity by type over a given time period; and/or one or more weather metrics such as temperature, humidity, precipitation, and/or sunlight intensity, and the dashboard application causes the normalized target energy usage value for the time period to be displayed and compared to the actual energy usage value. If a universal nominal target value is one of the inputs to the formula, that nominal target value is based on expected values of the extrinsic factors, and the nominal target value is normalized based on deviations from those expected values. Alternatively, the formula or algorithm may simply compute a target value directly from input or detected values of the extrinsic factors, eliminating the need for a nominal value to be entered into system 10. The formula or algorithm itself may be stored in local server 14 or elsewhere, and it may be updated globally for similarly situated restaurants by a central system administrator.

With reference to FIGS. 16-34, in a preferred embodiment, dashboard 22 not only monitors energy usage, but also monitors states and operation of restaurant devices 30, thus providing a single integrated application for controlling all equipment management needs of restaurant 28. This aspect of the invention is embodied in one example by user interface screens accessible via a temperature monitoring page, depicted in FIGS. 16-22, and screens accessible via a service alerts page, depicted in FIGS. 23-34. Typical state values that may be advantageous to measure, monitor, and/or control in a restaurant setting include, without limitation, temperatures of equipment, cooking mediums and/or food products; cooking medium levels; mechanical orientation of equipment components; air flows; and on/off equipment states. For example, a certain range of temperatures of a shortening medium in French fryer 36 may be required to properly cook quality French fries, and when one of sensors 50 detects and transmits to local server 14 and/or computing device 18 a shortening medium temperature outside of the required range, dashboard 22 will display an appropriate alert and present appropriate suggested actions. Similarly, freezers 38 and 40 must operate below a certain maximum temperature (typically 0° F., for example) to meet food safety standards, and if one of sensors 50 detects that either freezer 38 or 40 is operating above its maximum permitted temperature, an alert and troubleshooting actions will be displayed. In the case of grill 34, one of sensors 50 may detect whether its platens are level and parallel and dashboard 22 will display an alert and suggested responses if they are not level and parallel.

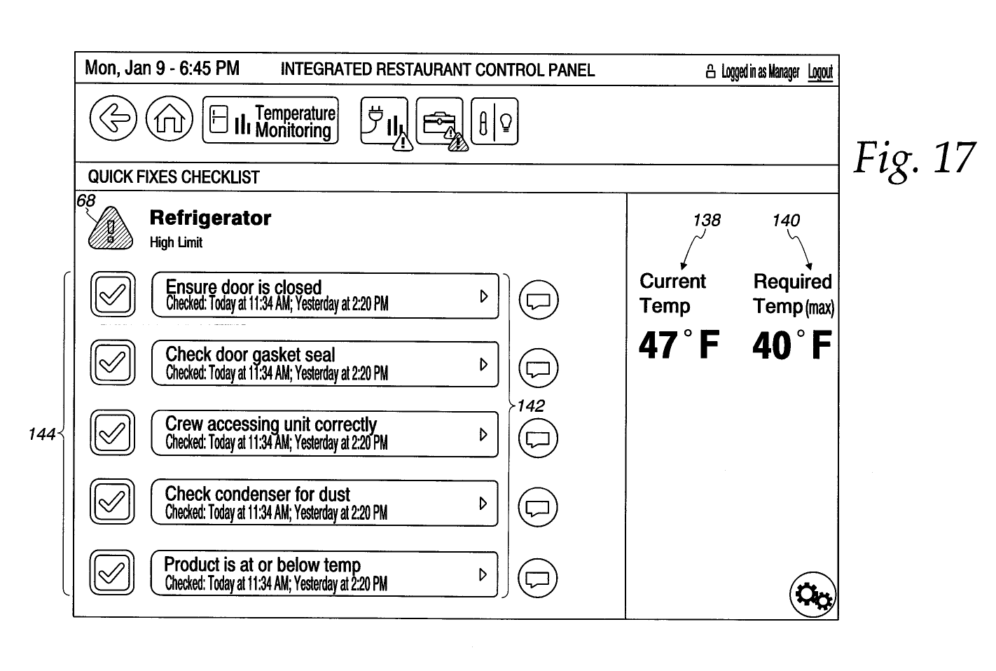

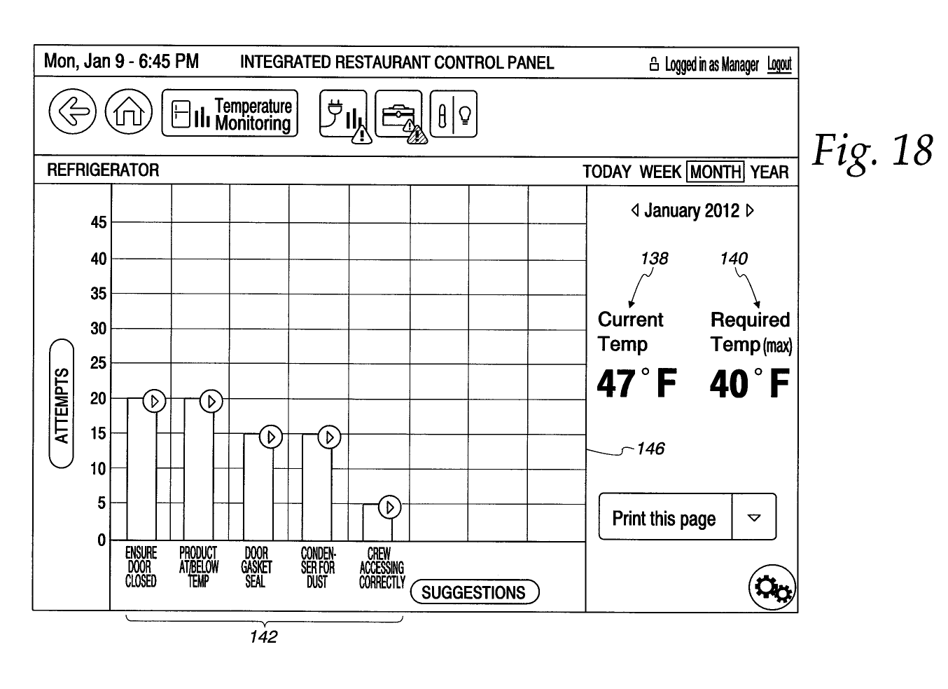

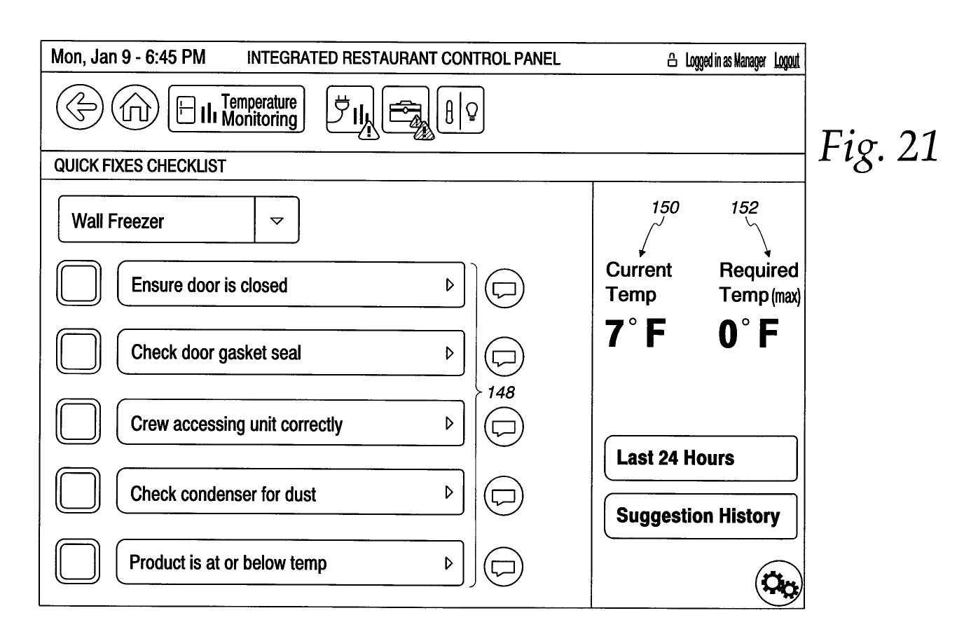

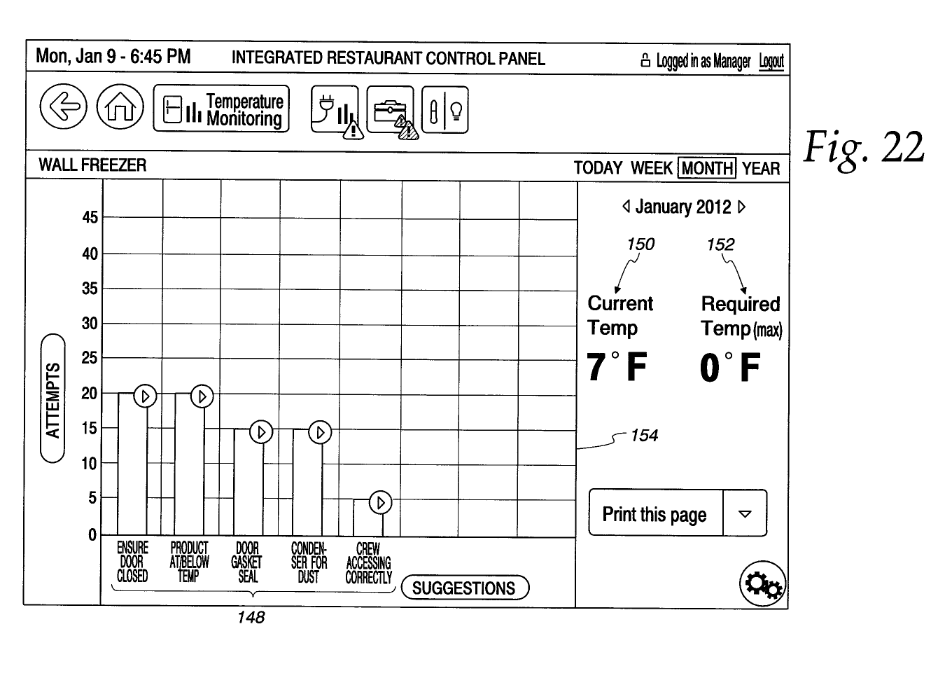

Turning to FIGS. 16-22, examples of temperature monitoring user interface screens will now be described. FIGS. 16-18 depict screens indicating that an actual refrigerator temperature 138 of 47° F. exceeds a high-limit temperature 140 of 40° F., and providing a checklist of quick fixes 142. FIG. 16 depicts quick fixes 142 that are presently suggested, and FIG. 17 depicts past user selections 144 of the same quick fixes 142, indicating the times at which the selections were made. Dashboard 22 thus includes a way of tracking the execution of recommendations. As illustrated in FIGS. 16 and 17, the execution tracking mechanism is manual and comprises simply prompting a user to check boxes indicating that a recommendation has been implemented. In another embodiment, the execution tracking mechanism is at least partially automatic, the dashboard application being programmed to cause computing device 18 and/or local server 14 to communicate with the appropriate restaurant devices 30 and/or sensors 50 of system 10 to determine automatically whether or not one or more recommendations have been implemented based on data transmitted from the devices 30 and/or sensors 50. Shown in FIG. 18 is a bar graph 146 logging the number of times each of quick fix suggestions 142 has been presented in January 2012. Shown in FIGS. 21 and 22 respectively, are a check list of suggestions 148 for a high temperature alert for a wall freezer having a current temperature 150 above a high limit temperature 152, and a bar graph 154 depicting a history of the same suggestions 148 in the month of January 2012, analogously to FIGS. 16 and 18 with respect to a refrigerator.

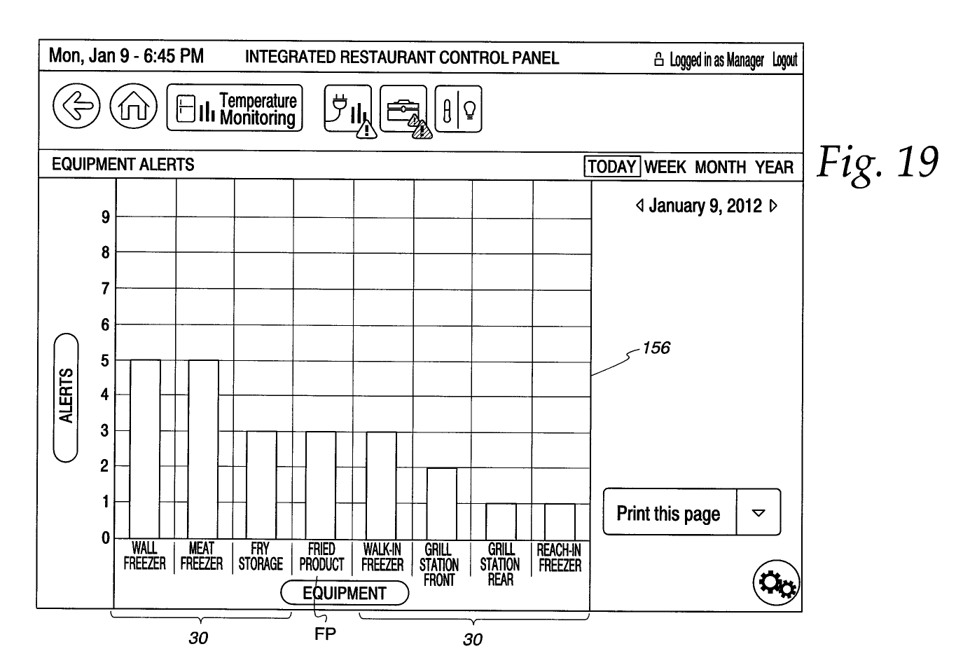

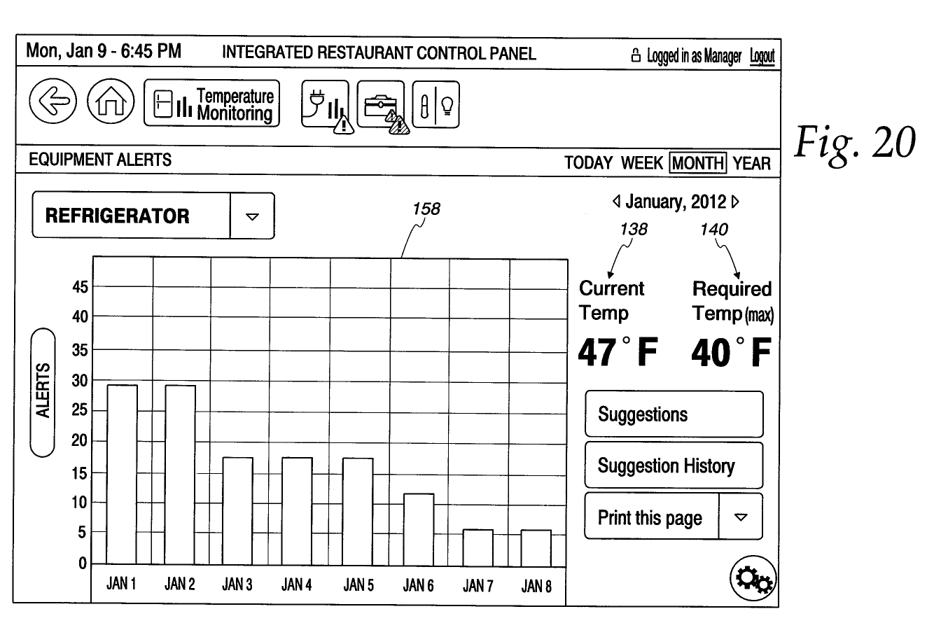

Turning to FIG. 19, the total number of temperature monitoring alerts for each of several restaurant devices 30 and one monitored product FP (“fried product”) on Jan. 9, 2012 is represented by a bar graph 156. In FIG. 20, the number of temperature monitoring alerts for a refrigerator only is broken down by day for January 2012 in a bar graph 158, while current temperature 138 and high limit temperature 140 of the refrigerator are again depicted numerically.

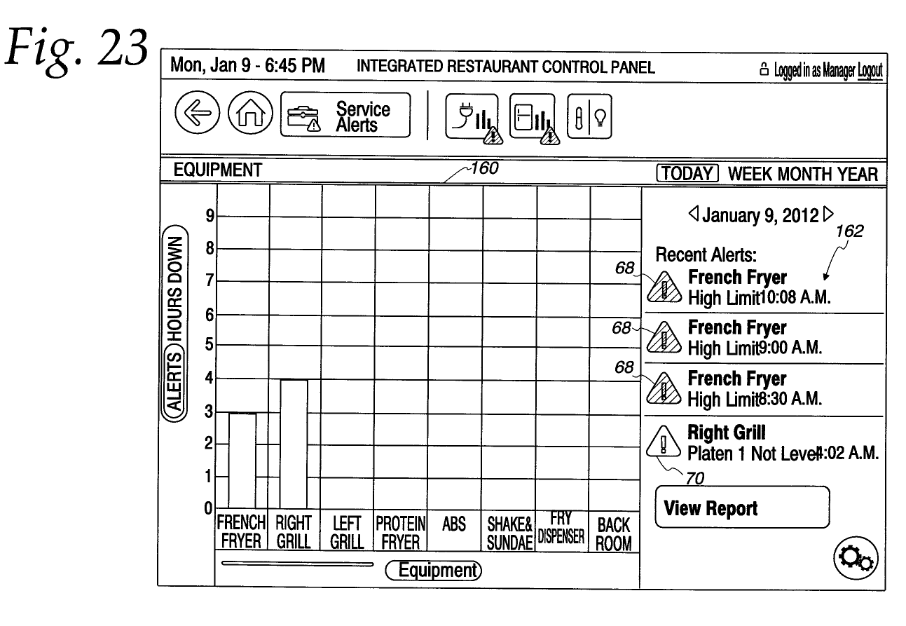

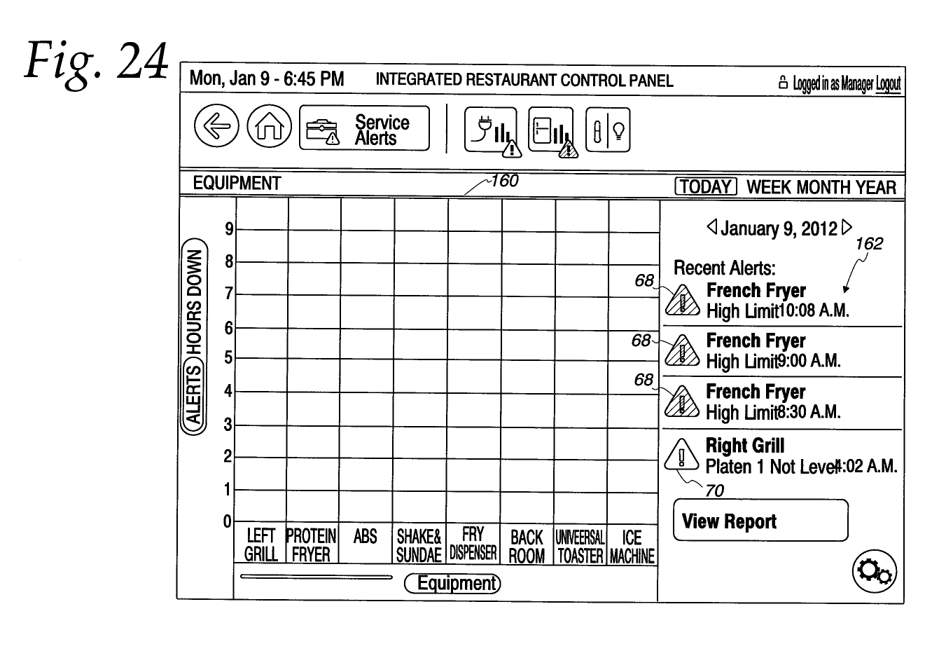

FIGS. 23 and 24 depict a bar graph 160 showing total numbers of alerts for various restaurant devices 30 on Jan. 9, 2012, in which all devices are not shown in a single view at one time. Rather, a user may scroll to the left (FIG. 23) and to the right (FIG. 24) to view information for desired devices 30. Concurrently in the right margin, recent alerts 162 are displayed individually, each alert marked with a high priority 68 (exceeding) or a normal priority icon 70. FIG. 25 shows a similar bar graph 164 totaling numbers of alerts for the week of Jan. 8-14, 2012 for various restaurant devices 30. Shown in FIG. 26 is a bar graph 166 depicting the number of hours down for each of several restaurant devices 30 on Jan. 9, 2012, while recent alerts 162 remain concurrently displayed in the right margin.

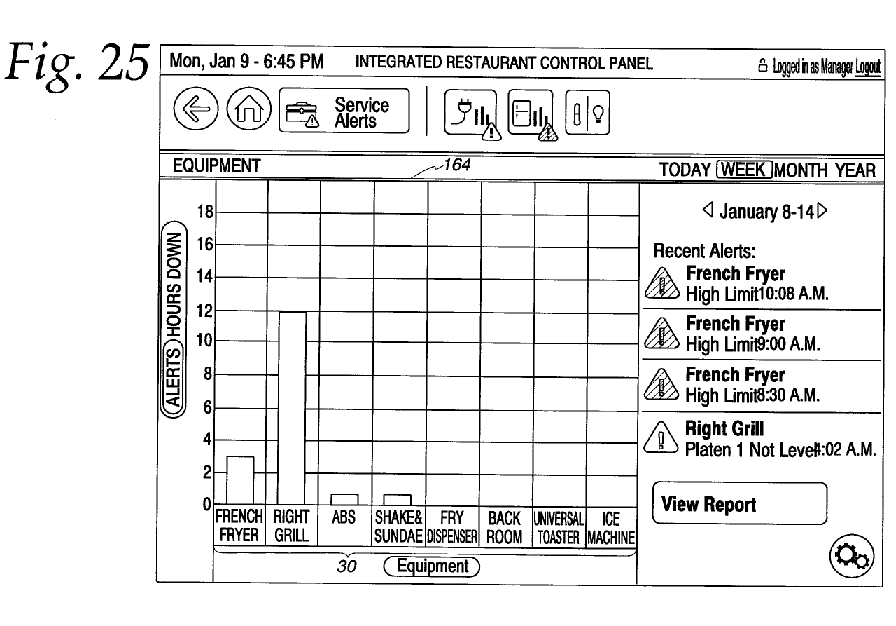

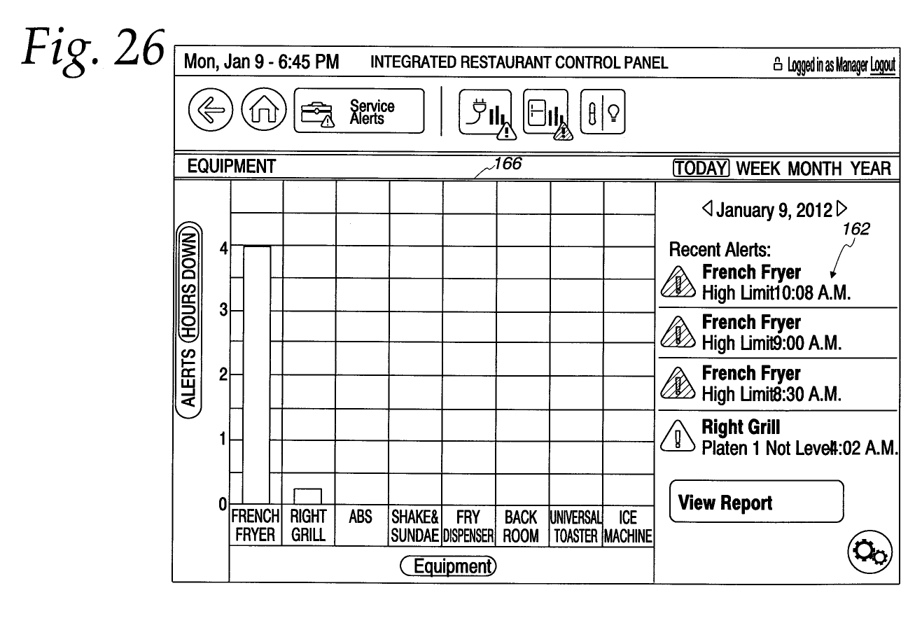

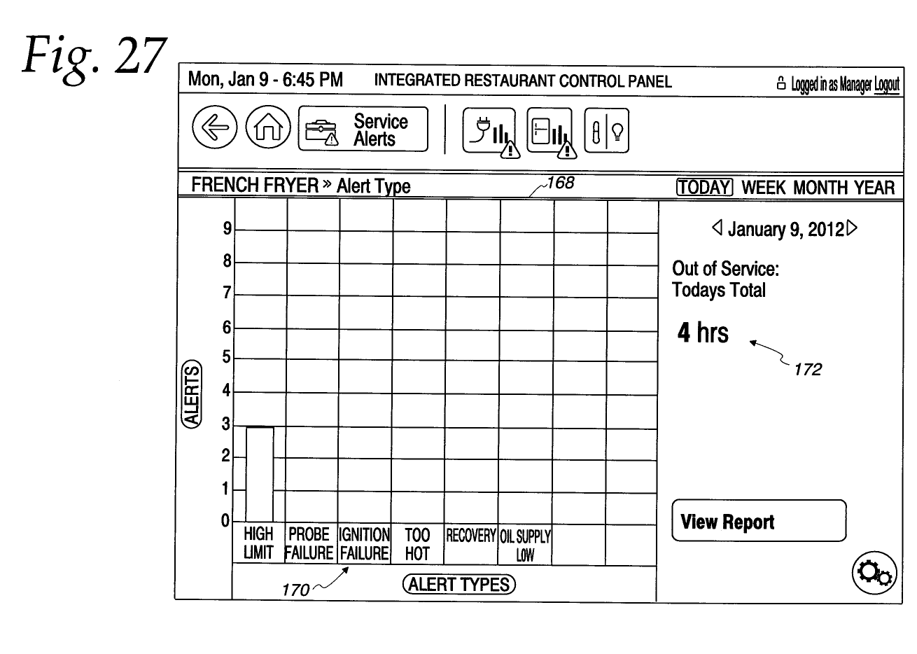

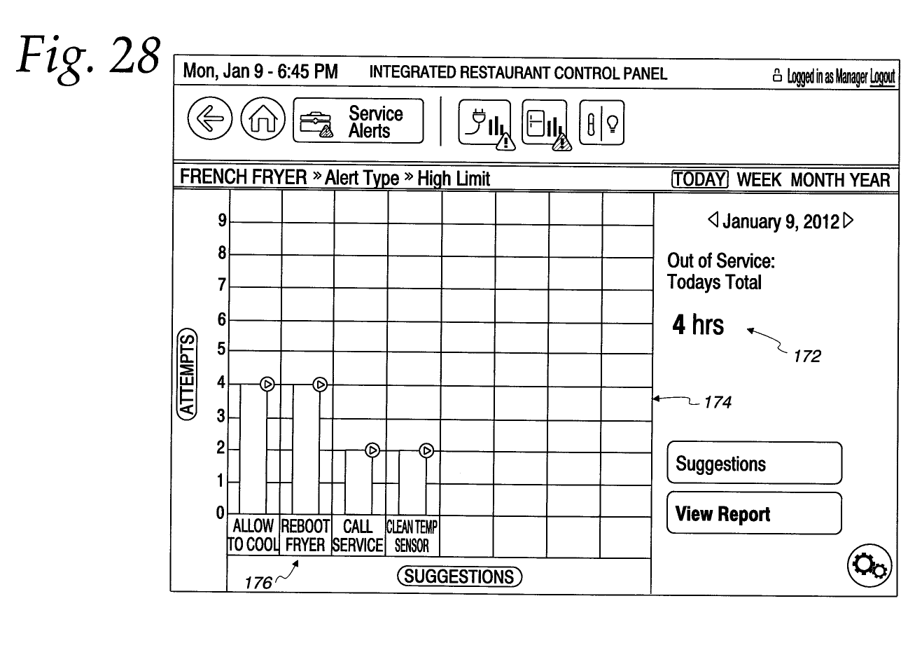

FIG. 27 depicts a bar graph 168 for only a French fryer, showing graphically a number of alerts on Jan. 9, 2012 for each of alert types 170, while a numerical indication 172 of total hours down for the French fryer is shown in the right margin. For the same day, FIG. 28 shows a bar graph 174 illustrating the number of each of suggestions 176 presented for the French fryer, while the total hours down indication 172 remains displayed in the right margin. FIG. 29 is an example of a related high limit alert message 178 for the French fryer, marked with a high-priority icon 68. The nature of the alert is indicated by a numerical current temperature 180 presented in the right margin, which exceeds a high limit temperature 182. Suggestions 184 are presented with check boxes 186 for user selection.

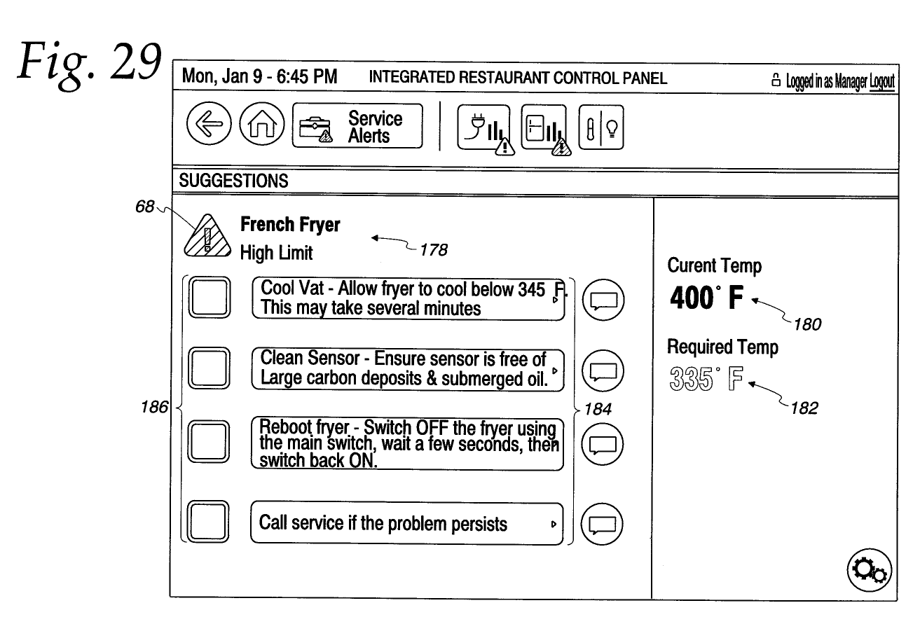

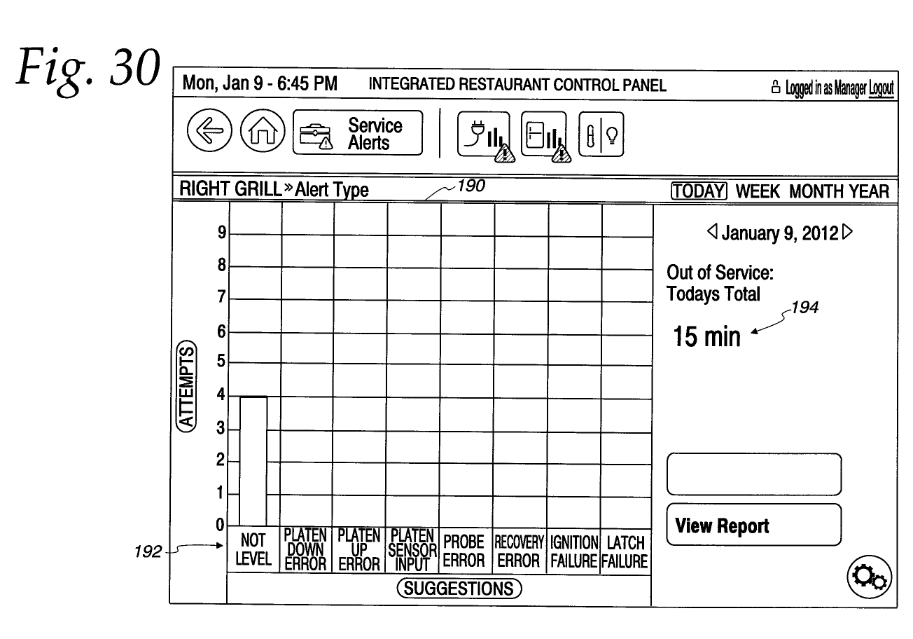

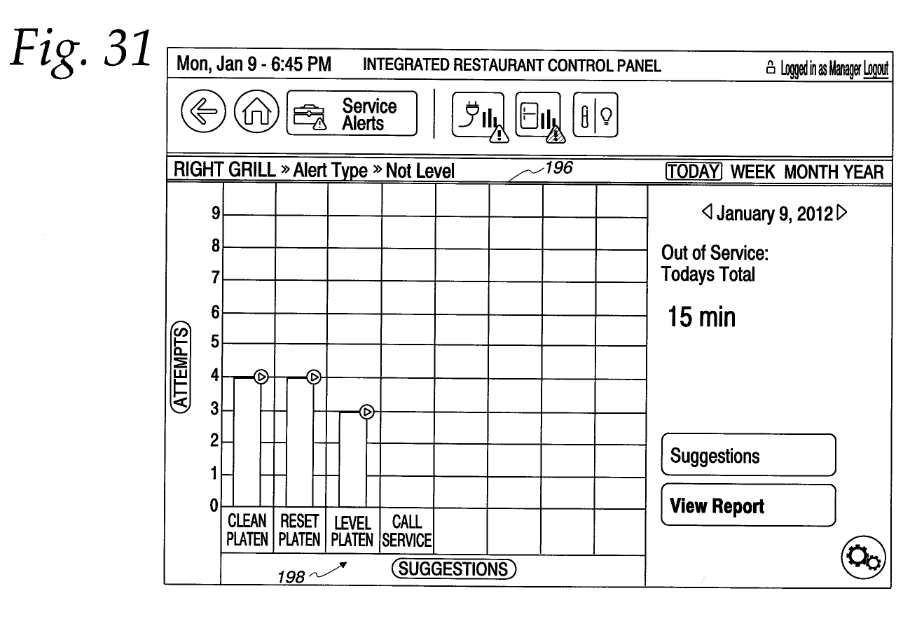

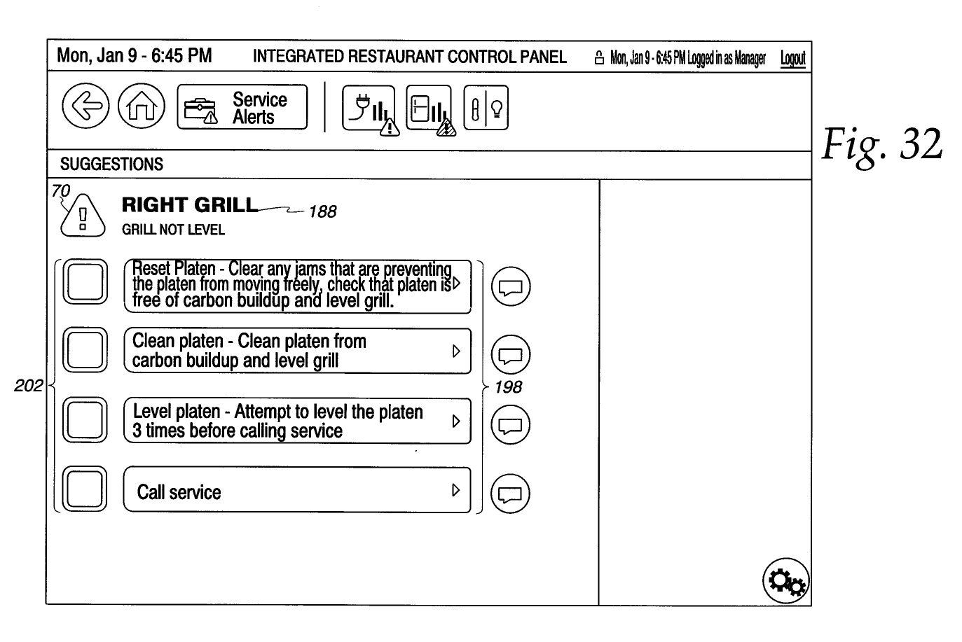

FIGS. 30-32 pertain to a “not level” alert 188 for a right grill, marked with a normal-priority icon 70 as seen in FIG. 32. FIG. 30 shows a bar graph 190 totaling alerts of various types 192 for the right grill, indicating only that four “not level” alerts have been presented on Jan. 9, 2012, while a daily out-of-service time total 194 of 15 minutes related to right grill alerts is depicted in the right margin. FIG. 31 includes a bar graph 196 of the number of times each of suggestions 198 has been selected on Jan. 9, 2012, while FIG. 32 depicts the alert 188 itself and corresponding suggestions 198 displayed with check boxes 202 for user selection.

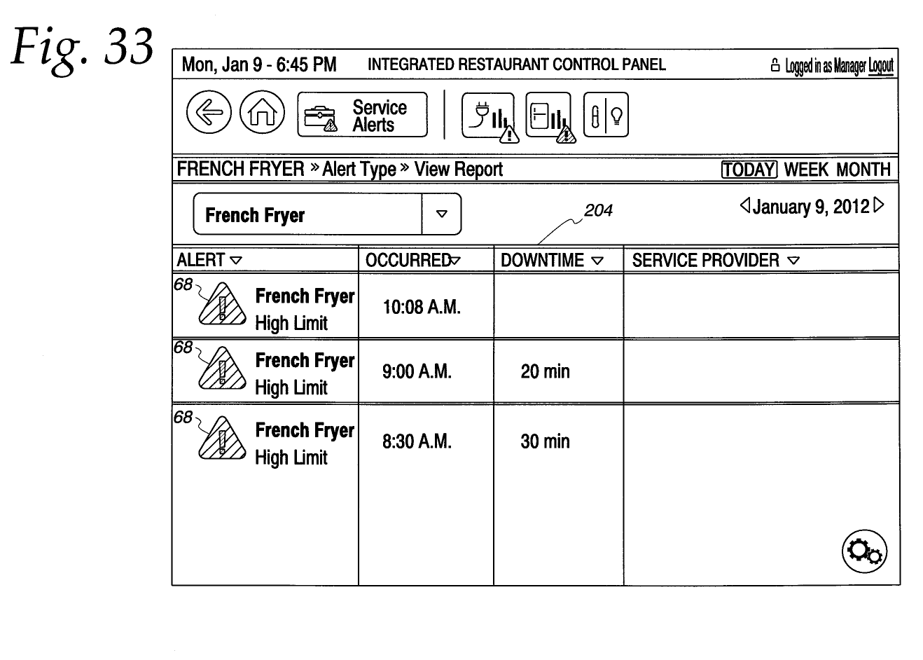

Examples of tabular representation of downtime information are given in FIGS. 33-34. In FIG. 33, table 204 represents a breakdown by time of incident and resulting downtime for each alert incident for a French fryer on Jan. 9, 2012. In FIG. 34, table 206 represents a daily breakdown of total alerts and total resulting downtime for the week of Jan. 8-14, 2012 for all restaurant equipment.

Although not depicted in the Figures, in the course of monitoring various states or parameters, such as energy consumption and operation of restaurant devices 30, dashboard 22 may advantageously integrate a system of tracking regular maintenance requirements. For example, in the case of HVAC unit 32 or other device that requires periodic maintenance on a run-time basis, dashboard 22 monitors run time to provide restaurant 28 with alerts of required preventative maintenance for HVAC unit 32 when a predetermined amount of run-time remains before the maintenance is due, such as filter replacement and spring up and fall shut-off maintenance requirements for air conditioning components.

Additional optional features can be incorporated into system 10. For example, one additional optional feature is the ability of system 10 to contact a service provider for support, system 10 providing appropriate information about one or more of restaurant devices 30, such as equipment condition or failure thereof. Contacting the service provider can be done by system 10 in a number of ways. System 10 may be configured to contact the service provider through any suitable medium, including but not limited to telephone, email, or text message, for example, either automatically or when prompted by a user. System 10 may contact the service provider under any of a number of conditions, for example: immediately after detection of an irregular state or energy usage condition, after dashboard 22 has presented a list of suggestions and a certain amount of time has elapsed without user input or without system 10 detecting that a user has implemented one or more of the suggestions, after a user has indicated the selection of one or more or all of a list of suggestions presented to a user by dashboard 22, after a user has indicated the selection of all of the suggestions presented and further indicated to system 10 via dashboard 22 that the problem has still not been resolved or system 10 has detected that the irregular state or energy usage condition is still present, after system 10 has detected that a user has implemented all of the suggestions and that the irregular state or energy usage condition is still present, or as otherwise desired.

In addition to monitoring restaurant devices 30, system 10 preferably includes self-monitoring functions, for example providing diagnosis and troubleshooting recommendations for sensors 50, locally (via messages displayed by dashboard 22) and/or remotely. Preferably, proper sensor operation is also capable of being verified by restaurant staff observing one or more of sensors 50 directly, such as by a digital readout of a quantitative measurement displayed on one or more of sensors 50 which restaurant staff can confirm is likely accurate, by a visually verifiable mechanical function of one of sensors 50, or by the presence or absence of one or more light or audio indicators of normal function or malfunction emanating from one of sensors 50. Low or no routine maintenance should be required of sensors 50 in accordance with the invention, but in case regular sensor maintenance is needed, dashboard 22 preferably provides an alert when a certain amount of run time or real time is remaining before sensor maintenance is due.

Tools and solutions provided by the invention include reporting and control functions at a restaurant and an enterprise level. It has already been noted that dashboard 22 is configured to display and compare energy usage data at restaurant 28 with corresponding data pertaining to other restaurants. In addition to restaurant 28, system 10 is preferably configured to permit remote monitoring and/or control of one or more other restaurants, such as at a restaurant 28′, as well as at additional restaurants (not shown), by administrative computing/client device 54 via remote server 53, as depicted schematically in FIG. 1.

In a preferred method of implementing system 10 in an existing restaurant, wireless frequencies used in communications between system 10 and restaurant devices 30 and among the various components of system 10 are selected not to interfere with frequencies used by existing restaurant equipment. Before full-scale implementation is carried out, wireless spectrum analysis inside a representative cross section of restaurants is preferably performed to determine that a system is non-interfering.

Alternatively or in addition to guiding restaurant staff responses to irregular energy use levels or equipment states, system 10 may also provide control functions. For example, dashboard 22 may include HVAC and lighting automated control system scheduling and override menus, as shown in FIGS. 35-53. (Although not illustrated in the Figures, system 10 may also include control functions for kitchen equipment, as described in more detail below.) Turning to FIG. 35, an ambient temperature control menu 208 and a lighting control menu 210 are depicted. Temperature control menu 208 includes for each of the kitchen, dining, and play place areas an occupied/vacant selection, scheduling, and override field 212, a current temperature indicator 214, a set-point temperature selection field 216, and a system mode (cool/heat e.g.) indicator/selection field 218 (when set to “auto,” as for the kitchen and play place areas, system 10 automatically switches the mode based on predefined conditions, whereas “locked,” as for the dining area, indicates that a user has manually selected the mode). A user thus potentially has the ability to modify any of selection fields 212, 216, and 218 to control the HVAC system or systems of a restaurant 28. For the kitchen area, a high priority low temperature alert 220 indicates that the kitchen temperature is 60° F., while the set point temperature is 68° F. The 8° F. difference between actual and set-point temperatures, despite system mode 218 being set on heat, suggests a likely heating problem, hence the alert. Similarly, lighting control menu 210 provides selection fields 222 by which a user may separately control the times when interior, exterior, signage, parking, and other lighting is turned on and off.

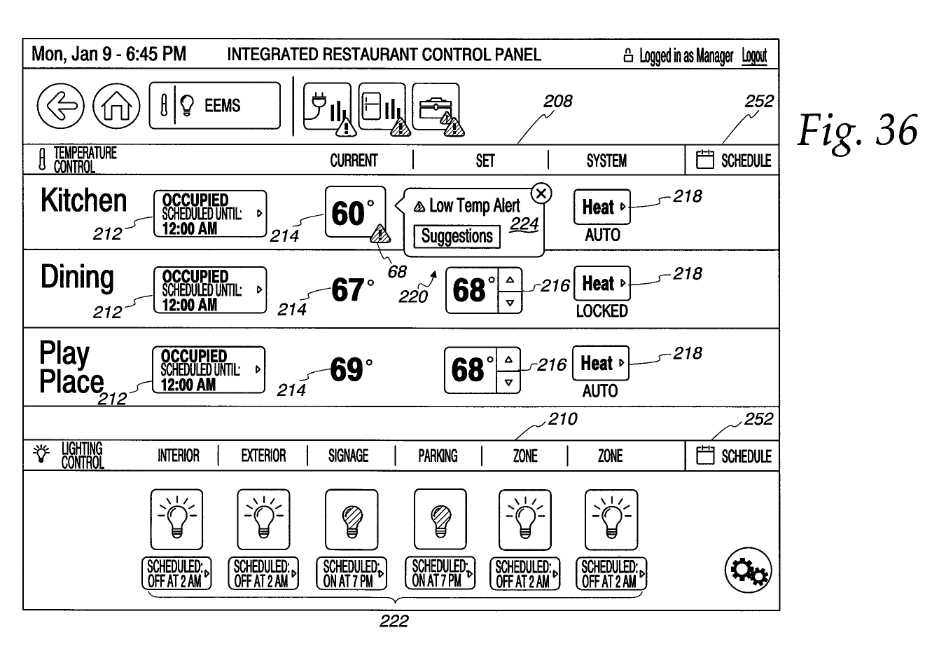

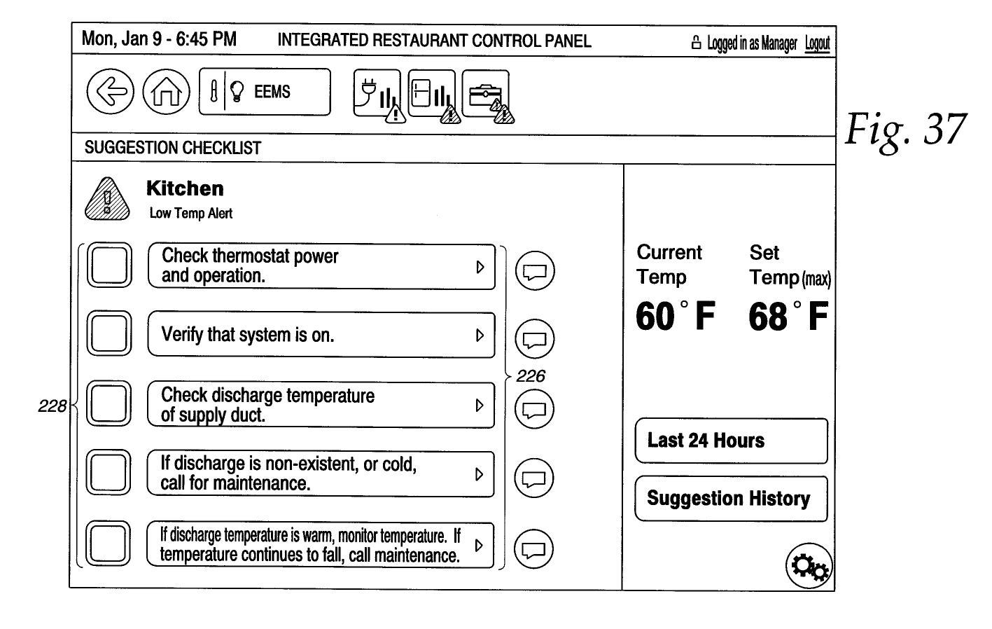

FIG. 36 depicts a pop-up message bubble 224 that appears when a user selects low temperature alert 220, from which bubble 224 a user is able to navigate to a list of suggestions 226 and corresponding selection check boxes 228 depicted in FIG. 37 for addressing the low kitchen temperature.

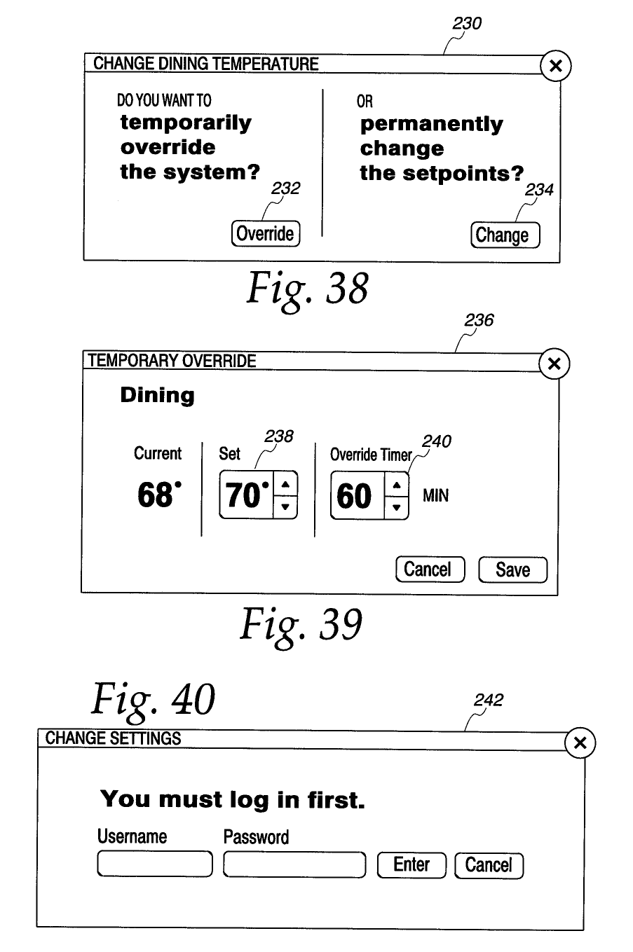

In FIGS. 38, 39 and 43, steps are illustrated for temporarily overriding the scheduled set-point temperature of the dining area and temporarily resetting that temperature from 68° F. to 70° F. Turning to FIG. 38, dialog box 230 may appear, for example, when a user attempts to adjust the dining area set-point temperature by touching the set-point temperature selection field 216 of temperature control menu 208 corresponding to the dining area. Dialog box 230 allows a user to select a temporary override of the dining area temperature by touching override button 232 or a permanent change by touching permanent change button 234. Touching override button 232 may bring up an override dialog box 236 shown in FIG. 39, which allows a user to adjust set point temperature in a selection field 238 and to select an override time duration in an override duration field 240. In this case, FIG. 39 illustrates a user changing the set point temperature to 70° F. and an override duration of 60 minutes. At any point in the override process, a login dialog box 242 may appear as shown in FIG. 40, requiring a user to log in by entering a username, password, and/or other information (not shown) before proceeding.

FIG. 43 depicts the same temperature and lighting menu screen shown in FIGS. 35 and 36, but an “override timer” message appears with a countdown time in the occupied/vacant selection, scheduling and override field 212 that corresponds to the dining area, indicating that a user has overridden the saved occupied/vacant settings, effective for the indicated time remaining. Additionally, the border of set-point temperature selection field 216 for the dining area is highlighted, as a visual cue that a user has specifically overridden the saved set-point temperature settings, in this case to temporarily change the dining area set-point temperature, saved as 68° F. for an occupied dining room as illustrated in FIGS. 35 and 36, to 70° F. In one embodiment, during an override, a user may adjust the overridden field, in this case the set-point selection field 216 corresponding to the dining area, by touching the up and down arrows directly within temperature control menu 208, without the need to repeat the step of selecting a temporary override in a separate dialog box as illustrated in FIG. 38.

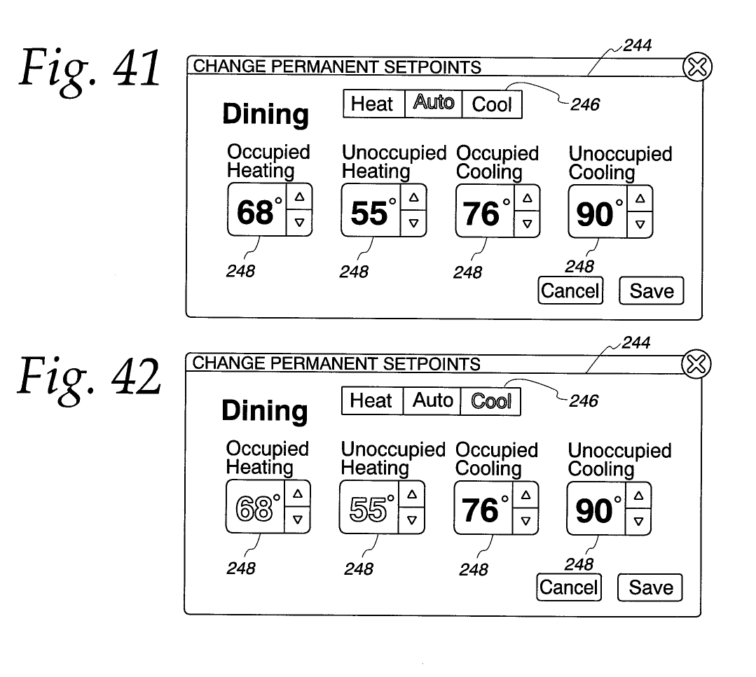

FIGS. 41-42 illustrate a dialog box 244 for permanently resetting scheduled set point temperatures, which may appear if a user presses the permanent change button 234 in dialog box 230. By selecting one of “heat,” “auto,” and “cool” modes 246, a user may then adjust occupied and unoccupied heat and cool set points in selection fields 248 as appropriate. In FIG. 42, in which a user has selected the “cool” mode, the occupied and unoccupied heating fields are “greyed out” and cannot be adjusted because they are inapplicable to the “cool” mode.

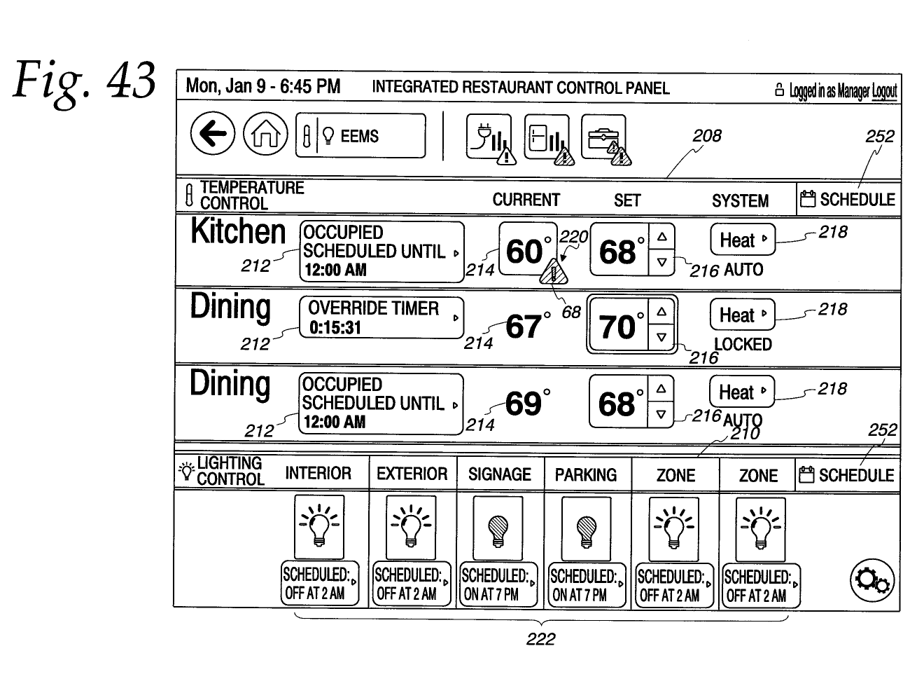

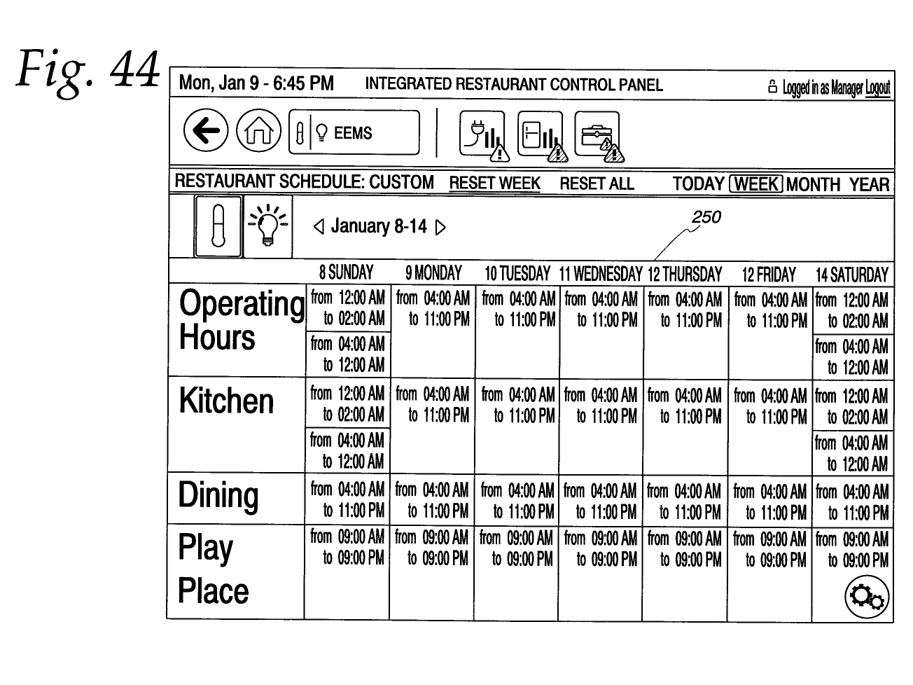

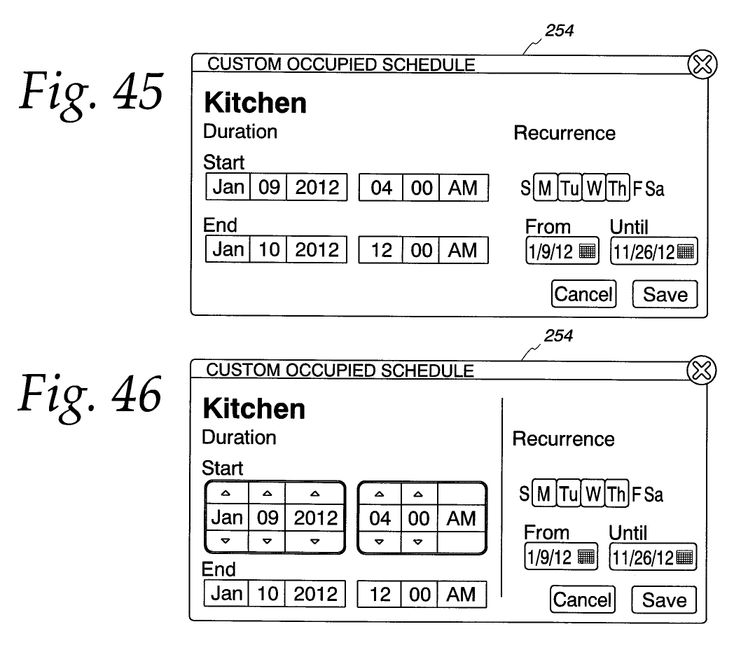

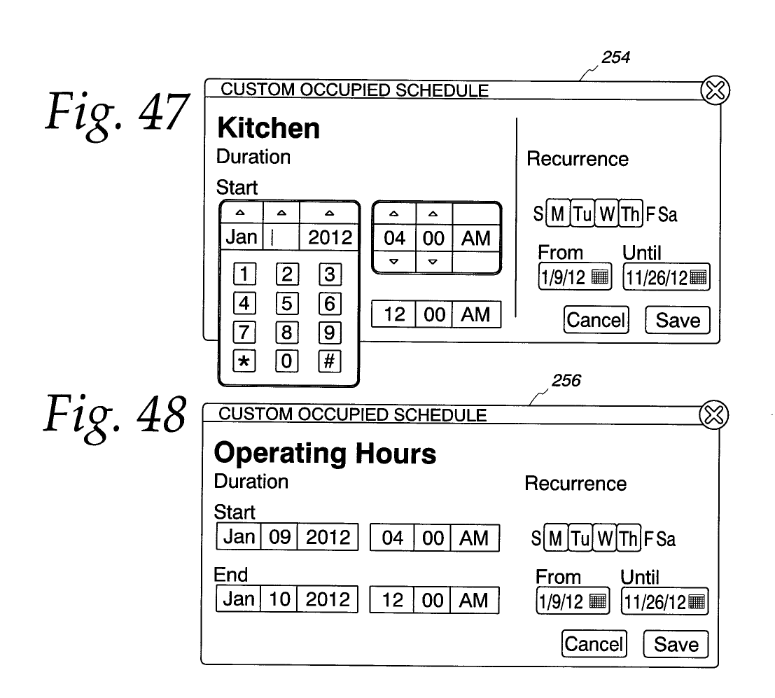

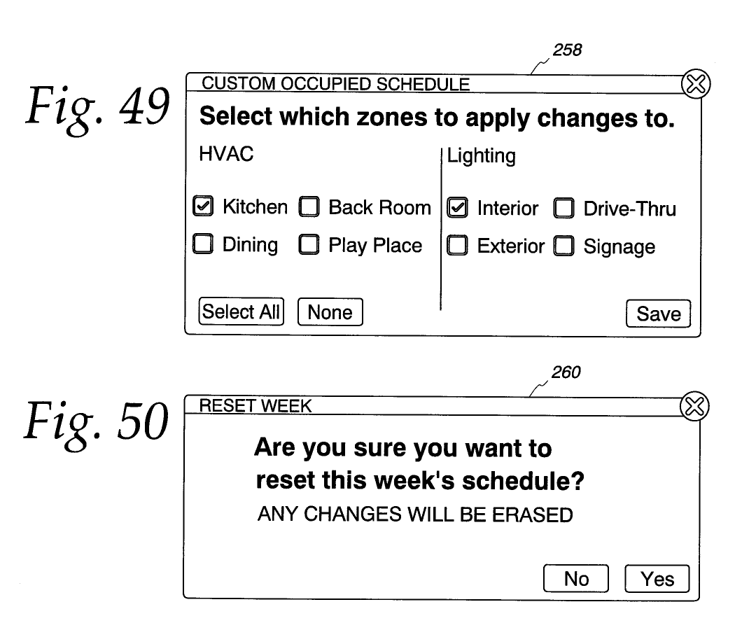

In FIGS. 44-53, user interface screens are shown to illustrate the process of creating custom schedules for temperature/HVAC or lighting control settings. FIG. 44 shows a temperature control (i.e., HVAC control) schedule table 250, which may appear when a user selects the schedule tab 252 shown in FIGS. 35, 36 and 43 that corresponds to temperature control menu 208. Schedule table 250 shows what may be a typical schedule defining operating hours of restaurant 28 and hours during which the kitchen, dining area, and play place are occupied, in which the operating and kitchen hours are the same, the dining area hours are shorter than the kitchen and operating hours, and the play place hours are shorter than the dining area hours. By touching the kitchen row of schedule table 250 or the occupied/vacant field 212 corresponding to the kitchen in temperature control menu 208, a user may bring up a kitchen custom occupied schedule dialog box 254 as in FIG. 45, permitting a user to customize the applicable start and end times, recurring days of the week, and start and end dates for a kitchen occupied schedule, by touching incremental arrows as shown in FIG. 46 or a touch keypad as shown in FIG. 47. Similarly, FIG. 48 depicts an operating hours custom occupied schedule dialog box 256 which may be brought up in an analogous manner. Once any custom occupied schedule changes have been entered and saved, a user is prompted by a zone selection dialog box 258, as shown in FIG. 49, to select zones to which the changes will be applied with respect to the corresponding HVAC and/or lighting systems. Any changes made to a custom occupied schedule may be deleted, returning the occupied schedule in question to its default settings, by selecting “reset week” or “reset all” in schedule table 250 shown in FIG. 44, which will bring up a corresponding confirmation dialog box, depicted by way of example in FIG. 50 as a reset week confirmation dialog box 260.

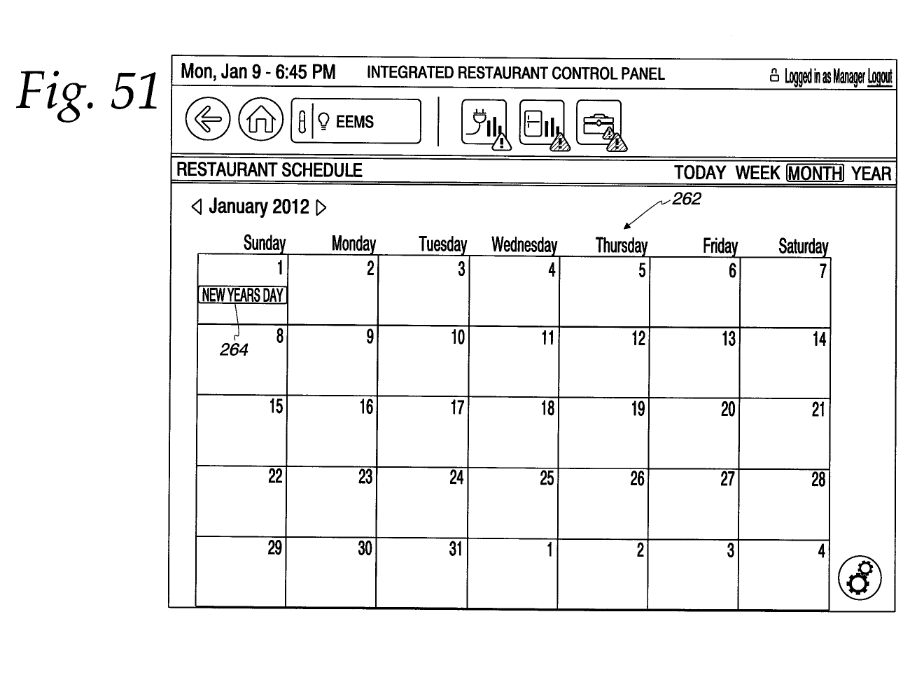

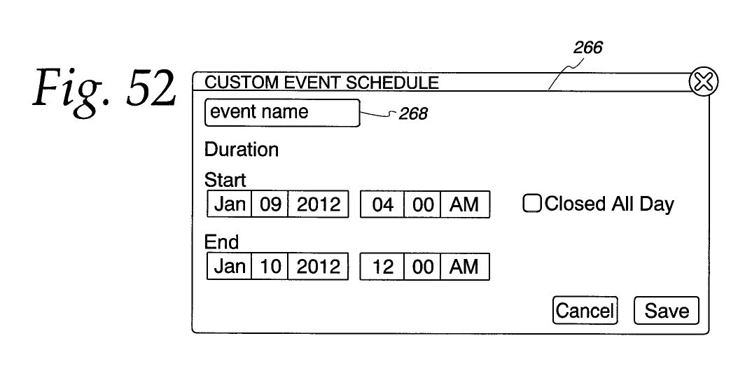

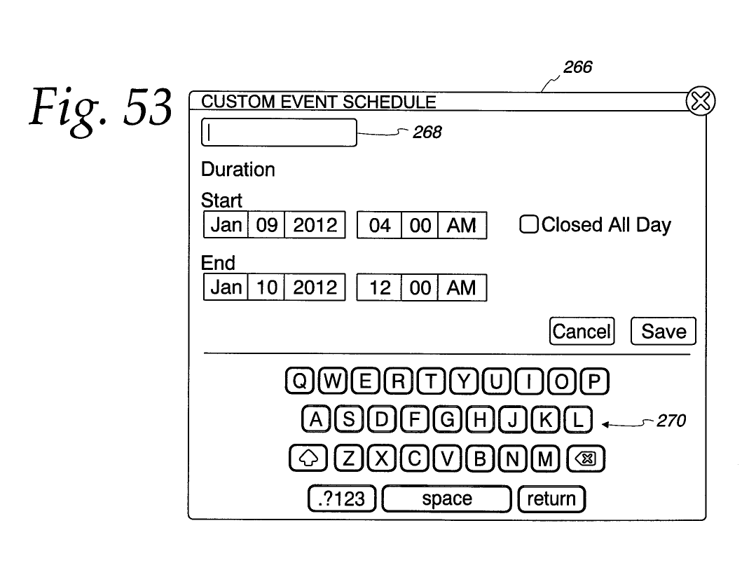

Depicted in FIG. 51 is a restaurant schedule calendar 262 for January 2012, depicting a holiday indicator 264 for New Year's Day in the box corresponding to Jan. 1, 2012. If a user wishes to assign special operating hours to an event such as New Year's Day or some other event, a user may, for example, touch the appropriate day box in calendar 262 to bring up a custom event dialog box 266 as illustrated in FIGS. 52-53. Custom event dialog box 266 permits a user to assign special operating hours, to indicate that restaurant 28 will be closed all day, and/or to name the custom event by touching a name field 268 to bring up a key pad 270 as shown in FIG. 53. The user having entered and saved the foregoing selections, the control settings of the appropriate HVAC and/or lighting systems will be set accordingly, and any name of the custom event will appear in calendar 262 in the corresponding day box.

In addition to the manual control functions described above with respect to FIGS. 35-53, system 10 may also provide automatic feedback control functions configured to correct irregular energy use levels and/or equipment states, whether of certain selected types or all types, whenever they are detected. For example, system 10 may be operatively connected to the power source of French fryer 36 and automatically switch French fryer 36 from an operating mode to a standby mode when one of sensors 50 detects that no French fries are being cooked in French fryer 36 for a certain amount of time in the operating mode. Similarly, system 10 may be configured to automatically shut off grill 34 when no cooking load is detected by one or more of sensors 50, which may be configured, for example, to detect a change in weight present on a platen or a rapid change in temperature at the surface of a platen due to the placement of a cold food item thereon. System 10 may also be operatively connected to a door closing motor (not shown) associated with one of freezers 38, 40 and configured to engage the motor to automatically close a freezer/oven door that one of sensors 50 detects to be open for a certain amount of time; to a power source to automatically turn off or dim parking lot or interior lighting that is inappropriately turned on or turned too high for certain detected conditions such as the time of day or the intensity of sunlight that is detected by one of sensors 50 either inside or outside of restaurant 28; to a thermostat to automatically adjust a thermostat set-point temperature under certain conditions, such as when a certain amount of time has elapsed during which restaurant staff has overridden a preset thermostat schedule; and/or to a fan or compressor motor to automatically adjust the operation of an air conditioning component of HVAC unit 32 on certain conditions; for example.

While the invention has been described with respect to certain embodiments, as will be appreciated by those skilled in the art, it is to be understood that the invention is capable of numerous changes, modifications and rearrangements, and such changes, modifications and rearrangements are intended to be covered by the following claims.

What is claimed is:

1. An integrated restaurant equipment monitoring system comprising
a data management component communicatively linked to at least one energy-monitored restaurant device and configured to automatically receive energy use data pertaining to the energy-monitored restaurant device; and
the data management component including a display device communicatively linked to a microprocessor and a memory;
the microprocessor programmed with instructions
to cause the display device to transmit an alert to a human user when the data management component receives an energy use value for the energy-monitored restaurant device that is higher than a target value, and
to cause the display device to display one or more suggested corrective actions for responding to the high energy use value.

2. The system of claim 1, further comprising at least one wireless sensor configured to sense the energy use data pertaining to the at least one energy-monitored restaurant device and to transmit the energy use data to the data management component.

3. The system of claim 2, further comprising a wireless router configured to relay the energy use data from the at least one wireless sensor to the data management component.

4. The system of claim 1, the at least one energy-monitored restaurant device including at least one kitchen device and at least one non-kitchen device.

5. The system of claim 1, the data management component further communicatively linked to at least one state-monitored restaurant device and configured to automatically receive state data pertaining to the at least one state-monitored restaurant device, and the microprocessor further programmed with instructions
to cause the display device to transmit an alert to a human user when the data management component receives state data for any state-monitored restaurant device indicating an irregular state of the restaurant device that is different from a target state or a range of target states, and
to cause the display device to display one or more suggested corrective actions for responding to the irregular state.

6. The system of claim 1, the data management component further communicatively linked to at least one maintenance-monitored restaurant device and configured to automatically receive data indicating when the at least one maintenance-monitored restaurant device requires regular maintenance, and the microprocessor further programmed with instructions to cause the display device to display a message indicating when the regular maintenance is required.

7. The system of claim 1,
the data management component further including a data input mechanism; and
the microprocessor further programmed with instructions
to cause the display device to display for each of the suggested corrective actions an estimate of the energy savings over a certain time period that would result from taking that corrective action,
to prompt a user to select one or more of the corrective actions using the data input mechanism,
to input any selection made by the user, and
to calculate and display an estimate of total energy savings over a certain time period that would result from taking all of the selected corrective actions.

8. The system of claim 7, the microprocessor further programmed with instructions to receive and store in the memory a utility rate and to use said utility rate to calculate and display said estimates of energy savings as monetary equivalent values.

9. The system of claim 8, the microprocessor further programmed with instructions to automatically query a remotely located server for said utility rate.

10. The system of claim 4, the at least one energy-monitored kitchen device including a kitchen device selected from the group consisting of a freezer, a refrigerator, a fryer, a grill, and the at least one energy-monitored non-kitchen device including a non-kitchen device selected from the group consisting of parking lot lights, an HVAC unit, interior lights.

11. The system of claim 1, the microprocessor further programmed with instructions
to cause to be stored in the memory an alert history including data pertaining to past instances of alert transmissions, and
to cause the display device to display the alert history data.

12. The system of claim 11, the alert history data including a total number of alerts transmitted for each restaurant device during one or more time periods.

13. The system of claim 1, the microprocessor further programmed with instructions
to cause to be stored in the memory an energy usage history including energy use data previously transmitted to the data management component,
to calculate from the energy usage history total amounts of energy used by each energy-monitored restaurant device and by all of the energy-monitored restaurant devices during one or more time periods, and
to cause the display device to display one or more of the total amounts of energy used, an indication of which device used the total amount of energy or that the total amount of energy is for all of the energy-monitored restaurant devices, and an indication of the relevant time period.

14. The system of claim 13, the microprocessor further programmed with instructions to receive and store in the memory one or more target amounts of energy corresponding to the displayed one or more of the total amounts of energy and to cause the display device to display the one or more target amounts of energy.

15. The system of claim 13, the microprocessor further programmed with instructions to receive and store in the memory one or more comparative amounts of energy used in other restaurants by a corresponding restaurant device or devices during a time period corresponding to the displayed one or more total amounts of energy and to cause the display device to display the one or more comparative amounts of energy.

16. The system of claim 13, the microprocessor further programmed with instructions to receive and store in the memory a utility rate and to use said utility rate to calculate and cause to be displayed said estimates of energy savings as monetary equivalent values.

17. The system of claim 13, the microprocessor further programmed with instructions to receive input data identifying for at least one of the energy-monitored restaurant devices one or more utility power sources used to provide energy to said at least one of the energy-monitored restaurant devices, to determine a utility rate for said power source, and to use said utility rate to calculate and cause to be displayed said estimates of energy savings as monetary equivalent values.

18. An integrated restaurant equipment monitoring system comprising
a data management component communicatively linked to at least one state-monitored restaurant device and configured to automatically receive state data pertaining to the state-monitored restaurant device; and
the data management component including a display device communicatively linked to a microprocessor and a memory;
the microprocessor programmed with instructions
to cause the display device to transmit an alert to a human user within a restaurant when the data management component receives an irregular state value for the state-monitored restaurant device, and
to cause the display device to display one or more suggested corrective actions for responding to the irregular state value.

19. The system of claim 18, the microprocessor further programmed to automatically determine from state data pertaining to the state-monitored restaurant device, received after the suggested corrective actions are displayed, whether a human user has executed one or more of the suggested corrective actions, and if the human user has not executed any of the suggested corrective actions after a predetermined amount of time has elapsed following the display of the suggested corrective actions, and the irregular state value is still detected after the predetermined amount of time, to automatically transmit a message to a human service provider outside the restaurant.

20. The system of claim 18, the microprocessor further programmed to automatically determine from state data pertaining to the state-monitored restaurant device, received after the suggested corrective actions are displayed, whether a human user has implemented one or more of the suggested corrective actions, and if the irregular state value is still detected after a predetermined amount of time following a determination that the user has executed one or more of the suggested corrective actions, to automatically transmit a message to a human service provider outside the restaurant.

21. An integrated restaurant equipment monitoring and control system comprising
a data management component communicatively linked to a plurality of state-monitored restaurant devices and configured to automatically receive state data pertaining to at least one of the state-monitored restaurant devices; and
the data management component including a microprocessor;
the microprocessor programmed with instructions
to determine whether an irregular state has been detected for any state-monitored restaurant device that is different from a target value or outside a target range of values, and
to automatically initiate an action to cause the irregular state to return to the target value or range of values.

22. The system of claim 21, the data management component further communicatively linked to at least one energy-monitored restaurant device and configured to automatically receive energy use data pertaining to the energy-monitored restaurant device; and
the microprocessor programmed with instructions
to cause a display device to transmit an alert to a human user when the data management component receives an energy use value for the energy-monitored restaurant device that is higher than a target value, and
to cause the display device to display one or more suggested corrective actions for responding to the high energy use value.

23. An integrated restaurant management method comprising
providing a data management component adapted to automatically receive energy use data from at least one energy-monitored device to which the data management component is communicatively connected, the data management component including a display device communicatively linked to a microprocessor and a memory, the microprocessor programmed with instructions to cause the display device to transmit an alert to a human user when the data management component receives an energy use value for the energy-monitored device that is higher than a target value, and to cause the display device to display one or more suggested corrective actions for responding to the high energy use value;
communicatively connecting the data management component to at least one energy-monitored restaurant device; and
when the display device transmits an alert indicating a high energy use value for an energy-monitored restaurant device and displays one or more suggested corrective actions for responding to the high energy use value, selecting and executing one or more of the suggested corrective actions.

24. The method of claim 23, further comprising inputting the selection of one or more of the suggested corrective actions into an input device of the data management component, the data management component being further configured to receive and store in the memory said selection.

25. The method of claim 24, the inputting the selection causing the data management component to initiate execution of the selected corrective action.

26. The method of claim 23, the data management component being further adapted to automatically receive state data from at least one state-monitored device to which the data management component is communicatively connected, and the microprocessor being further programmed with instructions to cause the display device to transmit an alert to a human user when the data management component receives data indicating an irregular state value for the state-monitored device that is different from a target state value or range of state values, further comprising
communicatively connecting at least one state-monitored restaurant device to the data management component; and
when the display device transmits an alert indicating an irregular state value for a state-monitored restaurant device and displays one or more suggested corrective actions for responding to the irregular state value, selecting and executing one or more of the suggested corrective actions.

27. An integrated restaurant management method comprising
providing a data management component communicatively linked to at least one state-monitored restaurant device and configured to automatically receive state data pertaining to the state-monitored restaurant device; and
the data management component including a display device communicatively linked to a microprocessor and a memory;
the microprocessor programmed with instructions
to cause the display device to transmit an alert to a human user within a restaurant when the data management component receives an irregular state value for the state-monitored restaurant device, and
to cause the display device to display one or more suggested corrective actions for responding to the irregular state value; and
when the display device transmits an alert and displays one or more suggested corrective actions, executing one or more of the suggested corrective actions.

28. The method of claim 27, the executing one or more of the suggested corrective actions being performed by a human.

29. The method of claim 27, the executing one or more of the suggested corrective actions being performed automatically by a restaurant equipment control system communicatively linked to the data management component.

30. The method of claim 27, the microprocessor further programmed with instructions to determine from state data pertaining to the state-monitored restaurant device, received after the suggested corrective actions are displayed, whether one or more of the suggested corrective actions has been executed, and if a predetermined amount of time has elapsed following a determination that a user has executed one or more of the suggested corrective actions, the irregular state value still being detected after the predetermined amount of time, to automatically transmit a message to a service provider outside the restaurant, the method further comprising
when the display device transmits an alert and displays one or more suggested corrective actions, executing one or more of the suggested corrective actions to cause the microprocessor to determine that the suggested corrective action has been executed,
after a predetermined amount of time has elapsed following the determination that the suggested corrective action has been executed, causing the microprocessor to automatically determine whether the irregular state value is still detected, and
if the irregular state value is still detected, causing the microprocessor to automatically transmit the message to the service provider.
